(19) United States
(12) Patent Application Publication
(10) Pub. No.: US 2025/0254937 A1
(43) Pub. Date: Aug. 7, 2025

(54) DIFFERENTIATED TRANSISTOR ISOLATION TECHNIQUES

(71) Applicant: Intel Corporation, Santa Clara, CA (US)

(72) Inventors: Philip Chung, Portland, OR (US); Kevin Cook, Portland, OR (US); Yuqian Gu, Hillsboro, OR (US); Abhishek Parija, Hillsboro, OR (US); Md Kamrul Alam, Beaverton, OR (US); Kalpana Besar, Hillsboro, OR (US); Pranav Dubey, Hillsboro, OR (US); Surya Cheemalapati, Beaverton, OR (US); Shathabish Narasegowda, Hillsboro, OR (US); Paul Morrow, Beaverton, OR (US); Ankit Kumar, Portland, OR (US)

(73) Assignee: Intel Corporation, Santa Clara, CA (US)

(21) Appl. No.: 18/433,833

(22) Filed: Feb. 6, 2024

(51) Int. Cl. H01L 29/06; H01L 21/8238; H01L 27/092; H01L 29/778; H01L 29/786

(52) U.S. Cl. CPC H10D 62/118; H10D 30/47; H10D 30/6757; H10D 84/0167; H10D 84/038; H10D 84/85

(57) ABSTRACT

Described herein are differentiated transistor isolation techniques. In one example, an integrated circuit structure may include transistors, where spacer structures or insulator regions that separate adjacent transistors from one another include one or more different materials. For example, an integrated circuit structure may include a first insulator region between first and second transistors, where the first insulator region includes a first insulator material (e.g., in the same layers as the channel regions of the transistors) and a second insulator material over the first insulator material. The IC structure may include a second insulator region between third and fourth transistors, where the second insulator region includes the second insulator material (e.g., in the same layers as the channel regions of the transistors).

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon field-effect transistor (FET), according to one embodiment of the present disclosure.

FIG. 2 is a top-down view of an IC device fabricated using differentiated transistor isolation techniques, according to one embodiment of the present disclosure.

FIGS. 3A-3B are cross-sectional side views illustrating an IC structure fabricated using differentiated transistor isolation techniques, according to some embodiments of the present disclosure.

FIG. 4 is a flow diagram of an example method for fabricating an IC structure using differentiated transistor isolation techniques, in accordance with some embodiments.

FIGS. 5A-5B, 6A-6B, 7A-7B, 8A-8C, 9A-9C, 10A-10C, 11A-11C, 12A-12C, 13A-13C, and 14A-14C are cross-sectional side views at various stages in the fabrication of an example IC structure according to the method of FIG. 4, in accordance with some embodiments.

FIG. 15 is a top view of a wafer and dies that may include any of the IC devices disclosed herein, in accordance with any of the embodiments disclosed herein.

FIG. 16 is a side, cross-sectional view of an IC package that may include any of the IC devices disclosed herein, in accordance with various embodiments.

FIG. 17 is a side, cross-sectional view of an IC device assembly that may include any of the IC devices disclosed herein, in accordance with any of the embodiments disclosed herein.

FIG. 18 is a block diagram of an example electrical device that may include any of the IC devices disclosed herein, in accordance with any of the embodiments disclosed herein.

### DETAILED DESCRIPTION

Disclosed herein are IC structures and devices fabricated with differentiated transistor isolation techniques. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

As IC structures become more compact with smaller feature sizes and higher device density, new challenges arise in the fabrication processes of such devices. For example, fabricating transistors may involve forming transistors in a line (e.g., in a stack of nanoribbons), where the transistors in the line are initially electrically connected to one another. The transistors may be electrically isolated from one another by forming a trench between adjacent transistors and filling the trench with an electrically insulating material to form discrete transistors. The material deposited into the trench can impact the performance of neighboring transistors. For example, some materials may cause tensile strain, while other materials may cause compressive strain on neighboring devices. In one example, tensile strain may cause a performance benefit for some devices (e.g., NMOS transistors) while compressive strain may cause a performance benefit for other devices (e.g., PMOS transistors). Thus, filling the trenches between different adjacent pairs of transistors with different materials may improve overall device performance.

However, filling the trenches between different adjacent pairs of transistors with different materials can prove to be a challenge, especially with high aspect ratio trenches. For example, if trenches are filled with a first insulator material, and the first insulator material is later removed from some openings in order to fill the openings with a second insulator material, the process of removing the first insulator material can result in excessive damage to side walls of the opening. In one such example, removing the first insulator material from a high aspect ratio opening can result in unintentional removal of liners from the sidewalls of the opening, which may result in electrical shorts and device failure.

In contrast, in one example, novel differentiated transistor isolation techniques can enable filling trenches between adjacent transistors with different materials to optimize performance for different types of transistors. In one example, a differentiated transistor isolation technique involves using a sacrificial material to selectively block deposition of an insulator material from some openings in order to fill those openings with a different insulator material. For example, a first opening between adjacent devices may be filled with a sacrificial material (such as a carbon-based hard mask material) to block the deposition of a first insulator material that is provided in a second opening between a second pair of adjacent devices. The sacrificial material can then be removed from the first opening, and a second insulator material can be provided in the first opening. In one such example, removal of the sacrificial material involves a process with high selectivity to materials on sidewalls of the opening, resulting in minimal damage to the opening. Thus, using a sacrificial material can enable filling trenches between different pairs of adjacent transistors with different materials to improve transistor performance.

IC structures as described herein, in particular IC structures fabricated using differentiated transistor isolation techniques, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

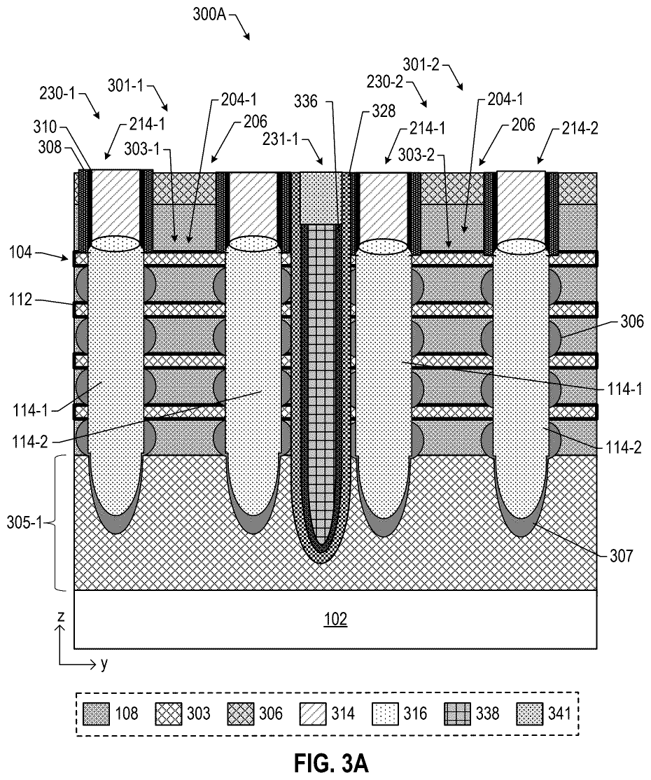

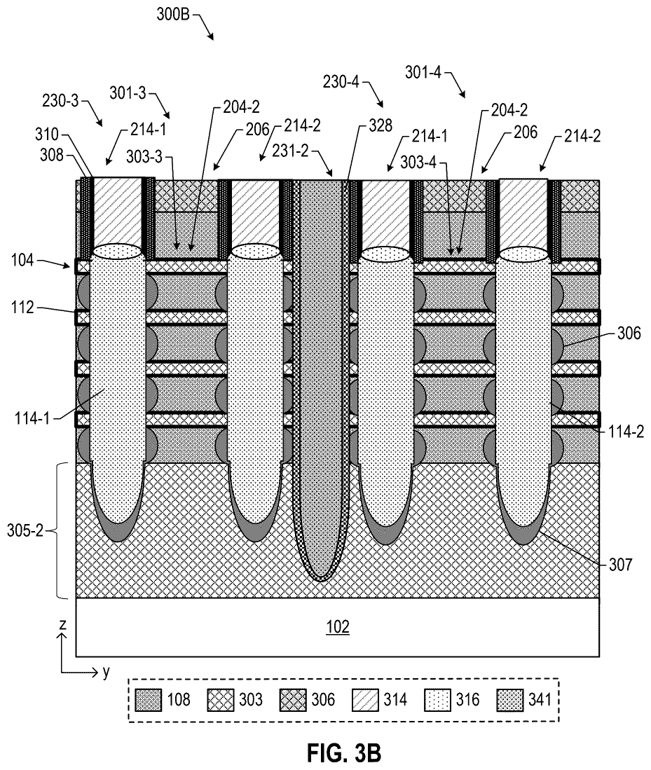

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 3A-3B, such a collection may be referred to herein without the letters, e.g., as “FIG. 3.”

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures fabricated using differentiated transistor isolation techniques as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

Fabrication of IC structures using differentiated transistor isolation techniques may be carried out with transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surfaces. A confinement surface refers to a particular orientation of the channel surface that is confined by the gate field. Non-planar transistors potentially improve performance relative to transistors having a planar architecture, such as single-gate transistors.

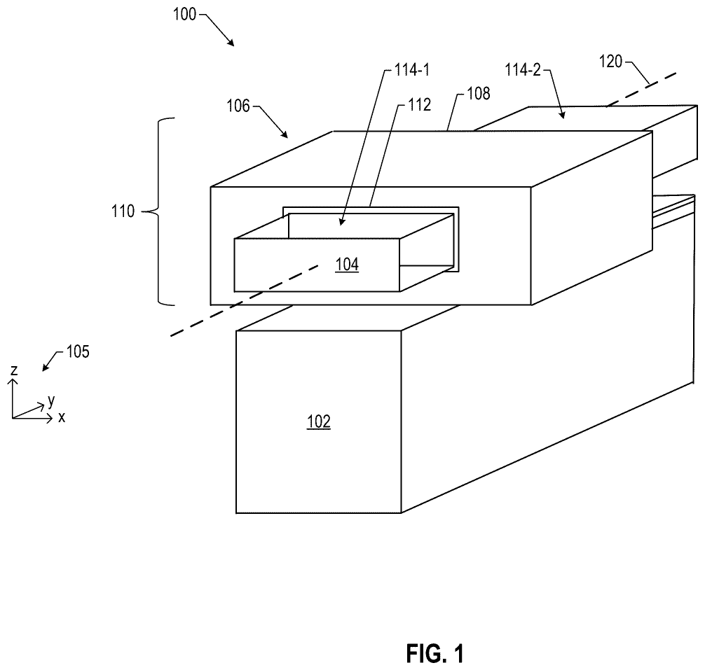

Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). Therefore, some IC structures illustrated herein show nanoribbon transistors as an example (e.g., IC structures shown in FIG. 1 and FIGS. 3A-3B), although fabrication of IC structures fabricated using differentiated transistor isolation techniques, described herein, is not limited to such transistors.

As used herein, the term “nanoribbon” refers to an elongated structure of a semiconductor material having a longitudinal axis parallel to a support structure (e.g., a substrate, a die, a chip, or a wafer) over which such a structure is built. Typically, a length of a such a structure (i.e., a dimension measured along the longitudinal axis, shown in the present drawings to be along the y-axis of an example x-y-z coordinate system 105 shown in FIG. 1) is greater than each of a width (i.e., a dimension measured along the x-axis of the coordinate system 105) and a thickness/height (i.e., a dimension measured along the z-axis of the coordinate system 105). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain regions of a transistor provided on either side of the channel material.

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2, on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

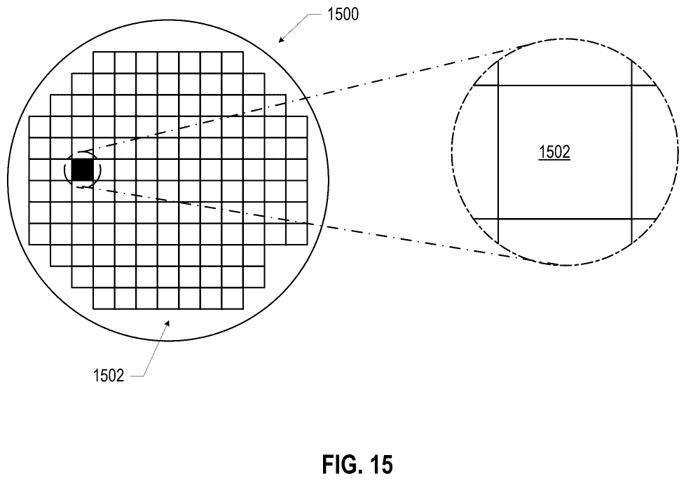

Implementations of the present disclosure may be formed or carried out on any suitable support 102, such as a substrate, a die, a wafer, or a chip. The support 102 may, e.g., be the wafer 1500 of FIG. 15, discussed below, and may be, or be included in, a die, e.g., the singulated die 1502 of FIG. 15, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. Although a few examples of materials from which the support 102 may be formed are described here, any material that may serve as a foundation upon which an IC structure fabricated using differentiated transistor isolation techniques as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another, e.g., as is shown in FIGS. 3A-3B, which show IC structures that may be examples of the IC structure 100. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of an x-y-z coordinate system 105 shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 102 and in a direction perpendicular to the longitudinal axis 120 of the nanoribbon 104, e.g., along the x-axis of the coordinate system 105) may be at least about 3 times larger than a height of the nanoribbon 104 (i.e., a dimension measured in a plane perpendicular to the support 102, e.g., along the z-axis of the coordinate system 105), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group Ill of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an NMOS transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a PMOS transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front-end components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a P-type metal-oxide-semiconductor (PMOS) transistor or an N-type metal-oxide-semiconductor (NMOS) transistor. For a PMOS transistor, gate electrode materials that may be used in different portions of the gate electrode material 108 may include, but are not limited to, ruthenium, palladium, platinum, cobalt, nickel, and conductive metal oxides (e.g., ruthenium oxide). For an NMOS transistor, gate electrode materials that may be used in different portions of the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabricate of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided above.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even when doped to realize threshold voltage tuning as described herein, the channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110, additional layers such as a spacer layer around the gate electrode of the transistor 110, etc.). For example, although not specifically illustrated in FIG. 1, a dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

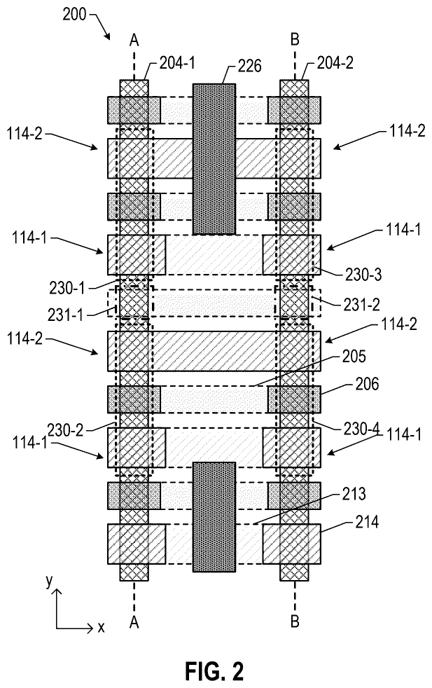

FIG. 2 is a top-down view of an IC structure 200 fabricated using differentiated transistor isolation techniques, according to one embodiment of the present disclosure. Some of the materials are not shown in the top-down view in order to not obscure the drawing.

As shown in FIG. 2, the IC structure 200 may include two nanoribbon stacks 204-1 and 204-2 (collectively referred to as “nanoribbon stacks 204”), if the transistors to be implemented in the IC structure 200 are nanoribbon transistors such as the one illustrated in FIG. 1. Alternatively, what is now shown as nanoribbon stacks 204-1 and 204-2 could be fins, if the transistors to be implemented in the IC structure 200 are FinFETs. The nanoribbon stacks 204 may include stacks of one or more nanoribbons 104 as described above, and may be provided over a support such as the support 102 (not specifically shown in FIG. 2). The nanoribbon stacks 204 may extend substantially parallel to one another, e.g., along the y-axis of the coordinate system 105, consistent with the illustration of FIG. 1. Metal gate lines 205 (shown in FIG. 2 to be within dashed contours) and S/D contact lines 213 may extend substantially perpendicular to the nanoribbon stacks 204 and substantially parallel to one another, e.g., along the x-axis of the coordinate system 105. FIG. 2 illustrates that the metal gate lines 205 and the S/D contact lines 213 may be provided in an alternating manner. Metal gate lines 205 may intersect the gate contacts 206 that are in conductive contact with the gate stacks 106 (which are underneath the gate contacts 206 and, therefore, not seen in the view of FIG. 2) provided over channel portions of the nanoribbon stacks 204, providing electrical connectivity to the gates of the nanoribbon transistors. Thus, portions of the gate contacts 206 intersecting the gate stacks 106 are in conductive contact with the gate stacks 106 and serve as gate contacts for the transistors. Similarly, S/D contact lines 213 may intersect the S/D contacts 214 provided over S/D regions 114 (which are underneath the S/D contacts 214 and, therefore, not seen in the view of FIG. 2) of the nanoribbon stacks 204, providing electrical connectivity to the S/D regions 114 of the nanoribbon transistors. Thus, portions of the S/D contacts 214 intersecting the S/D regions 114 are in conductive contact with the S/D regions 114 and serve as S/D contacts for the transistors.

FIG. 2 further illustrates that deep trench vias 226 may be provided in the vicinity of the transistors formed on the basis of the nanoribbon stacks 204. Two instances of the deep trench vias 226 are shown in FIG. 2, but, in other embodiments, any other number of one or more deep trench vias 226 may be included in the IC structure 200. Similarly, while a particular arrangement of gate stacks 106, metal gate lines 205, gate contacts 206, S/D contact lines 213, and S/D contacts 214 is shown in FIG. 2, in other embodiments, these elements may be arranged differently within the IC structure 200.

In order to further illustrate details of the IC structure 200, FIG. 2 shows portion 230-1-230-4 (illustrated with a dotted contour) to indicate an approximate outline of example transistors such as the transistor 110, provided over the nanoribbon stacks 204-1, 204-2. In one example, adjacent transistors in a nanoribbon stack are electrically separated from one another by regions of one or more insulator materials in the nanoribbon stack. For example, the adjacent transistors in the portions 230-1 and 230-2 are separated from one another by a region 231-1. Similarly, the adjacent transistors in the portions 230-3 and 230-4 are separated from one another by a region 231-2.

FIGS. 3A and 3B are cross-sectional side views along different cross-sections of the IC structure 200 of FIG. 2, according to some embodiments of the present disclosure. In particular, FIG. 3A illustrates a cross-sectional side view of the portions 230-1 and 230-2 along a plane AA shown in FIG. 2, and FIG. 3B illustrates a cross-sectional side view of the portions 230-3 and 230-4 along a plane BB shown in FIG. 2. A number of elements referred to in the description of FIGS. 3A-3B with reference numerals are illustrated in these drawings with different patterns, with a legend showing the correspondence between the reference numerals and patterns being provided at the bottom of each drawing page containing FIGS. 3A-3B. For example, the legend illustrates that FIGS. 3A-3B use different patterns to show a gate electrode material 108, a semiconductor material 303, an electrically conductive material 306 of a gate contact 206, and so on.

As shown in FIG. 3A, the portion 230-1 includes a transistor 301-1 and the portion 230-2 includes a transistor 301-2 similar to the transistor 110 but built on the basis of a nanoribbon stack 204-1 of a plurality of nanoribbons 104 instead of just one nanoribbon 104 as shown in FIG. 1. While four nanoribbons 104 are shown to be included in the nanoribbon stack 204-1, in other embodiments, fewer nanoribbons 104 or more nanoribbons 104 may be included. Similarly, as shown in FIG. 3B, the portion 230-3 includes a transistor 301-3 and the portion 230-4 includes a transistor 301-4 similar to the transistor 110, but with four nanoribbons 104 in the nanoribbon stack 204-2. FIGS. 3A-3B illustrate a semiconductor material 303 as the material of the nanoribbons 104, further illustrating a subfin (e.g., subfins 305-1, 305-2, each of which may be referred to herein as a subfin 305) of the semiconductor material 303 below the respective nanoribbon stacks 204-1, 204-2, although in some embodiments the nanoribbons 104 and at least a portion of the subfins 305-1, 305-2 may include materials of different material compositions. As shown in FIGS. 3A-3B, gate stacks 106 having a gate insulator material 112 and a gate electrode material 108 may wrap around channel portions of the nanoribbons 104. FIGS. 3A-3B further illustrate a first S/D region 114-1 and a second S/D region 114-2 of each of the transistors 301-1-301-4 extending through the respective nanoribbon stacks 204-1, 204-2, electrically insulated/separated from the gate electrode material 108 and from the semiconductor material 303 of the subfin 305 by an insulator material 307. In some embodiments, the insulator material 307 may form so-called “dimples” 306 in areas where the insulator material 307 separates the S/D regions 114-1, 114-2 from the gate electrode material 108. The insulator material 307 may include any of the insulator materials described herein, e.g., any of the ILD materials described above.

Above the nanoribbon stacks 204-1, 204-2, FIGS. 3A-3B illustrate a gate contact 206 and S/D contacts 214-1, 214-2 on either side of the gate contact 206 for each of the transistors 301-1-301-4. The first S/D contact 214-1 is for making electrical contact to the first S/D region 114-1 and the second S/D contact 214-2 is for making electrical contact to the second S/D region 114-2 of each of the transistors 301-1-301-4. The gate contact 206 may include an electrically conductive material 306 in electrically conductive contact with the gate electrode material 108. In various embodiments, material compositions of the electrically conductive material 306 and the gate electrode material 108 may be substantially the same or different.

The S/D contacts 214 may be electrically isolated from the gate electrode material 108 and the electrically conductive material 306 of the gate contact 206 by gate spacers 308. The gate spacers 308 may include one or more of spacer materials, diffusion barrier materials, adhesion materials, etc., as known in the art for forming contacts to various components of IC structures. In some embodiments, the gate spacers 308 may include low-k dielectrics and/or any of the ILD materials described above. Optionally, sidewalls of the S/D contacts 214 may be lined with one or more liners 310, where the liners 310 may include, but not limited to, materials comprising silicon and nitrogen (e.g., silicon nitride), materials comprising silicon and oxygen (e.g., silicon oxide), materials comprising silicon and carbon (e.g., silicon carbide), and/or their composites. Within the sidewalls, the S/D contacts 214 may be filled with an electrically conductive fill material 314. In various embodiments, material compositions of the electrically conductive fill material 314 and the electrically conductive material 306 may be substantially the same (e.g., both may include/be tungsten) or different. At the bottom of the S/D contacts 214, an interface material 316 is deposited to provide an interface between the S/D regions 114 and the electrically conductive fill material 314 of S/D contacts 214. The interface material 316 may include/be a metal such as titanium which, once deposited, may intermix with the material of the S/D regions 114, e.g., with silicon, forming a compound (e.g., titanium silicide) that may help reduce contact resistance of the S/D contacts 214.

As can be seen in FIGS. 3A and 3B, adjacent transistors are separated from one another by regions 231-1, 231-2 of one or more insulator materials. Specifically, the transistors 301-1, 301-2 of FIG. 3A are separated by the region 231-1, and the transistors 301-3, 301-4 of FIG. 3B are separated by the region 231-2. The regions 231-1, 231-2 include one or more insulator materials to electrically insulate or isolate the adjacent transistors from one another. Thus, the regions 231-1, 231-2 may be referred to as insulator regions, isolation regions, or transistor spacer structures. Unlike conventional IC structures, different adjacent pairs of transistors may be electrically separated by spacer structures having different materials, which can enable improving transistor performance for different transistors. For example, FIG. 3A shows first and second transistors 301-1, 301-2 with respective first and second channel regions 303-1, 303-2 in a first nanoribbon stack 204-1. Similarly, FIG. 3B shows third and fourth transistors 301-3, 301-4 with respective third and fourth channel regions 303-3, 303-4 in a second nanoribbon stack 204-2. The IC structure of FIG. 3A includes a first insulator region (e.g., the region 231-1) in the first nanoribbon stack 204-1 between the first and second transistors 301-1, 301-2, and the IC structure of FIG. 3B includes a second insulator region (e.g., the region 231-2) in the second nanoribbon stack 204-1 between the third and fourth transistors 301-3, 301-4.

In one example, the region 231-1 of FIG. 3A includes a first insulator material 338 and a second insulator material 341 over the first insulator material 338, where the first insulator material 338 has one or more different material properties from the second insulator material 341 (e.g., a different material composition, density, dielectric constant, structural difference such as crystallinity, etc.). In contrast, in the example illustrated in FIG. 3B, the region 231-2 is filled with the second insulator material 341, but not the first insulator material. Thus, the regions 231-1, 231-2 between different adjacent pairs of transistors include different insulator materials (e.g., insulator materials having one or more different material properties, such as a different material composition and/or other different material properties). By filling the regions 231-1, 231-2 with different insulator materials, the performance of different transistors can be tuned by, for example, using materials that cause different strain on the neighboring transistors. In one example, the first insulator material 338 includes an oxide (e.g., silicon oxide) and the second insulator material includes a nitride (e.g., silicon nitride). In one such example, silicon oxide can cause tensile strain on the neighboring transistors (which may be beneficial for NMOS transistors), while silicon nitride can cause compressive strain on neighboring transistors (which may be beneficial for PMOS transistors). Thus, in the example illustrated in FIGS. 3A-3B, the region 231-1 includes the first insulator material 338 in a bottom portion and the second insulator material 341 in the top portion of the region, while the second region 231-2 is filled only with the second insulator material 341. In other examples, the regions 231-1, 231-2 can include additional or different materials than silicon oxide and/or silicon nitride. Although compressive and tensile strain are mentioned as specific examples of material attributes, other material properties (e.g., such as the material's dielectric constant or other properties) may have an impact on the performance of neighboring devices.

As mentioned above, the regions 231-1, 231-2 include different insulator materials in the same layer or planes as the channel regions of the transistors adjacent to the regions 231-1, 231-2. For example, the region 231-1 of FIG. 3A includes the first insulator material 338 in the same layers with one or more of the channel regions 303-1, 303-2, and the region 231-2 of FIG. 3B includes the second insulator material 341 in the same layers with one or channel regions 303-3, 303-4. In the example illustrated in FIG. 3A, the region 231-1 also includes the second insulator material 341 in a layer over the first insulator material 338. For example, the first insulator material 338 may be present in a first plane with a channel region (e.g., a bottom or a top channel region of the channel regions 303-1, 303-2), and the second insulator material 341 of the region 231-1 may present in a second plane that is above the channel regions (e.g., in a same plane as a contact structure, such as the S/D contacts 214 or gate contacts 206 of the first or second transistors 301-1, 301-2). In one such example, the ratio of the volume of the first insulator material 338 to the second insulator material 341 depends on the dimensions of other elements of the IC structure. In one example where the region 231-1 has a first volume of the first insulator material 338 and a second volume of the second insulator material 341, the ratio of the first volume to the second volume is in a range of about 1:1 to 1:9. In contrast, the region 231-2 of FIG. 3B includes the second insulator material 341 in a same layer or plane as the channel regions 303-3, 303-4 and in a same layer or plane as contact structures of the third and fourth transistors. In one such example, the volume of the second insulator material 341 in the region 231-2 of FIG. 3B is about the same as the combined volume of the first insulator material 338 and the second insulator material 341 in the region 231-1 of FIG. 3A.

In one example, the region 231-1 of FIG. 3A includes a continuous portion of the first insulator material 338 that extends below and above the channel regions 303-1, 303-2 (e.g., into the subfins 305-1, 305-2 and into a layer over the channel regions 303-1, 303-2). In one such example, the region 231-1 includes a continuous portion of the first insulator material 338 in a first plane below a first source or drain region (e.g., below the S/D region 114-2 of the transistor 301-1 and/or below the S/D region 114-1 of the transistor 301-2). In one such example, a continuous portion of the second insulator material 341 is in a second plane above S/D regions 114-1, 114-2 and in contact with the continuous portion of the first insulator material 338. Referring now to FIG. 3B, in one example, the region 303-2 includes a continuous portion of the second insulator material 341 in the first plane and in the second plane (e.g., a continuous second insulator material that extends below and above the S/D region 114-2 of the transistor 301-3 and/or below and above the S/D region 114-1 of the transistor 301-4).

The regions 231-1, 231-2 separating adjacent transistors may include one or more liners on sidewalls and/or bottoms of the regions 231-1, 231-2. In one example, the regions 231-1, 231-2 both include a liner 328 on sidewalls of the regions 231-1, 231-2. In one example, the liner 328 includes a conformal liner of a material that acts as a barrier between the materials in the regions 231-1, 231-2 and the neighboring transistors. In one such example, the liner 328 includes a third insulator material that is different from the first insulator material 338 and second insulator material 341. In one example, the liner includes one or more of silicon, oxide, carbon, and nitride, and may include silicon oxycarbonitride (SiOCN). In other examples, the liner 328 may include a different insulator material or may be absent from some or all portions of the sidewalls of the regions 231-1, 231-2.

In the example illustrated in FIG. 3A, the region 303-1 also includes another liner 336 between the first insulator material 338 and the liner 328. In one example, the liner 336 acts as an adhesion layer (e.g., between the first insulator material 338 and the materials that the first insulator material 338 is or was in contact with during fabrication of the IC structures). In one example, the liner 336 may include a fourth insulator material. In one example, the liner 336 is present between the transistors 301-1, 301-2 and the first insulator material 338, but absent between the transistors 301-1, 301-2 and the second insulator material 341. In one such example where the first insulator material is silicon oxide, the liner 336 may also include silicon oxide, but may include one or more different material properties (e.g., to make the liner 336 effective as an adhesion layer). In the example illustrated in FIG. 3A, the liners 328 and 336 are also lining the bottom of the region 231-1 (e.g., the liners 328, 336 are present between the first insulator material 338 and the material 303 of the subfin 305-1). Similarly, in the example illustrated in FIG. 3B, the liner 328 lines the bottom of the region 231-2. In other examples, different or additional liner materials are possible.

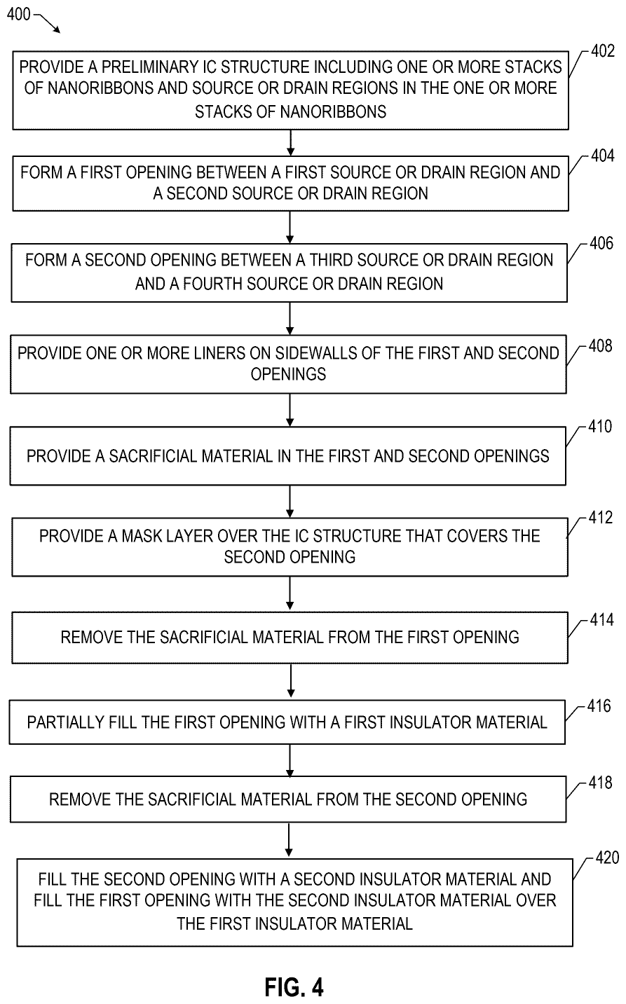

FIG. 4 is a flow diagram of an example method for fabricating an IC structure using differentiated transistor isolation techniques, in accordance with some embodiments. Although the operations of the method of FIG. 4 are illustrated once each and in a particular order, the operations may be performed in any suitable order and repeated as desired. For example, one or more operations may be performed in parallel to fabricate multiple IC structures using differentiated transistor isolation techniques substantially simultaneously. In another example, the operations may be performed in a different order to reflect the structure of an IC device in which differentiated transistor isolation techniques will be implemented.

In addition, the example fabricating method of FIG. 4 may include other operations not specifically shown in FIG. 4, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 4 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

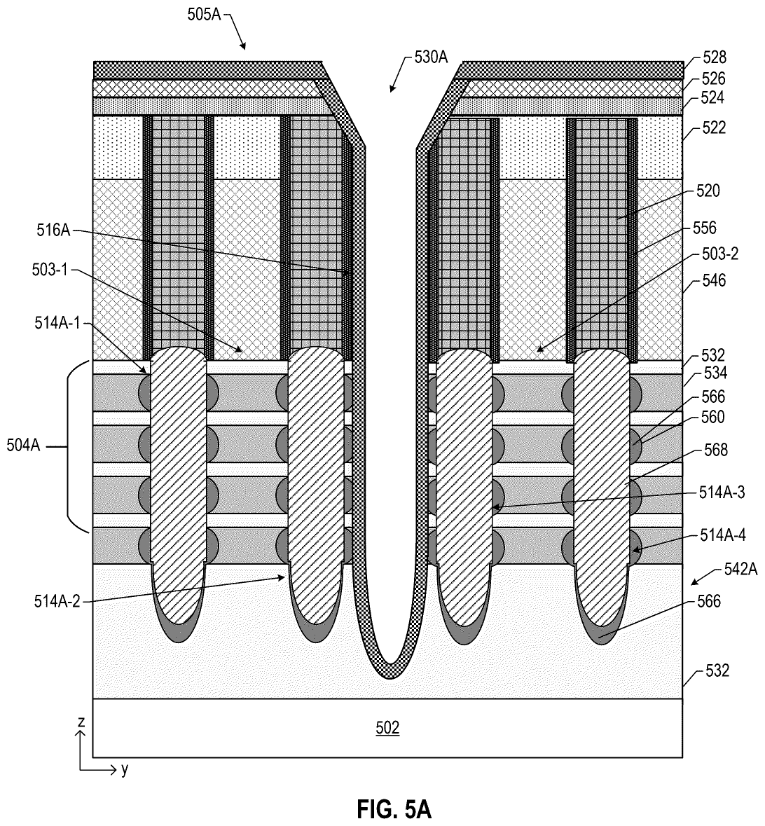

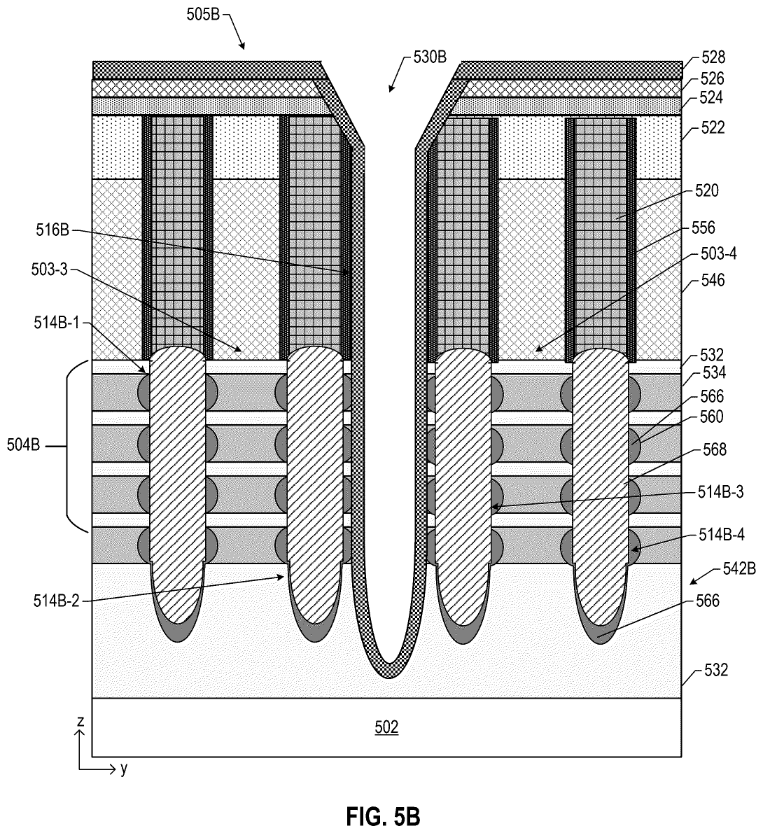

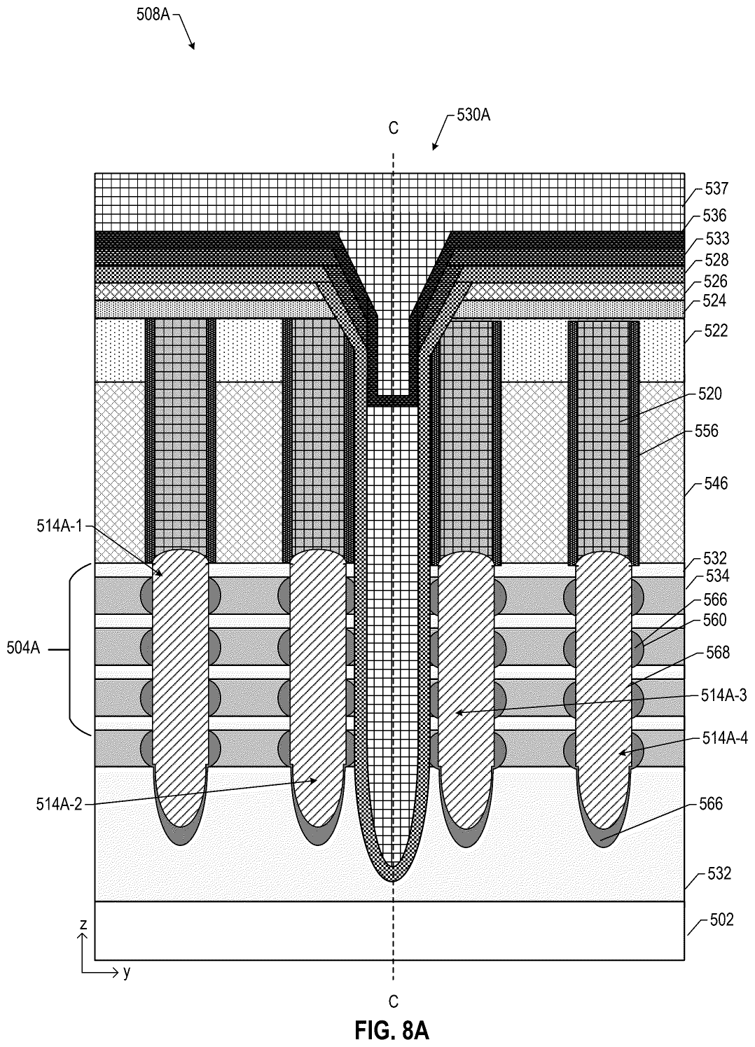

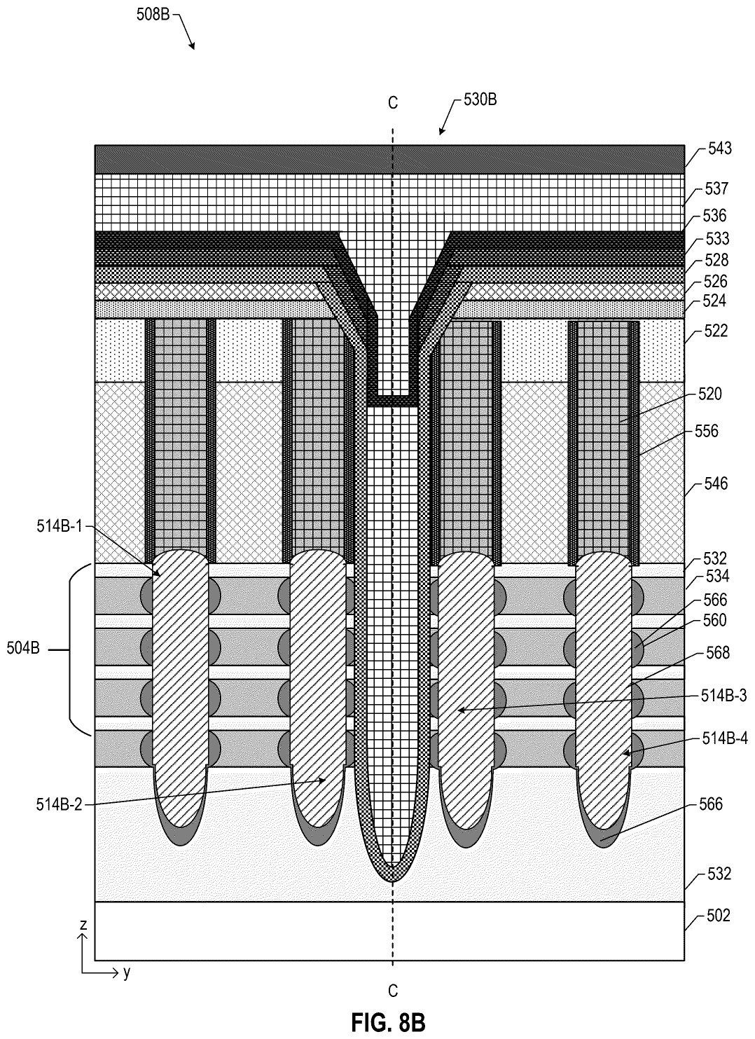

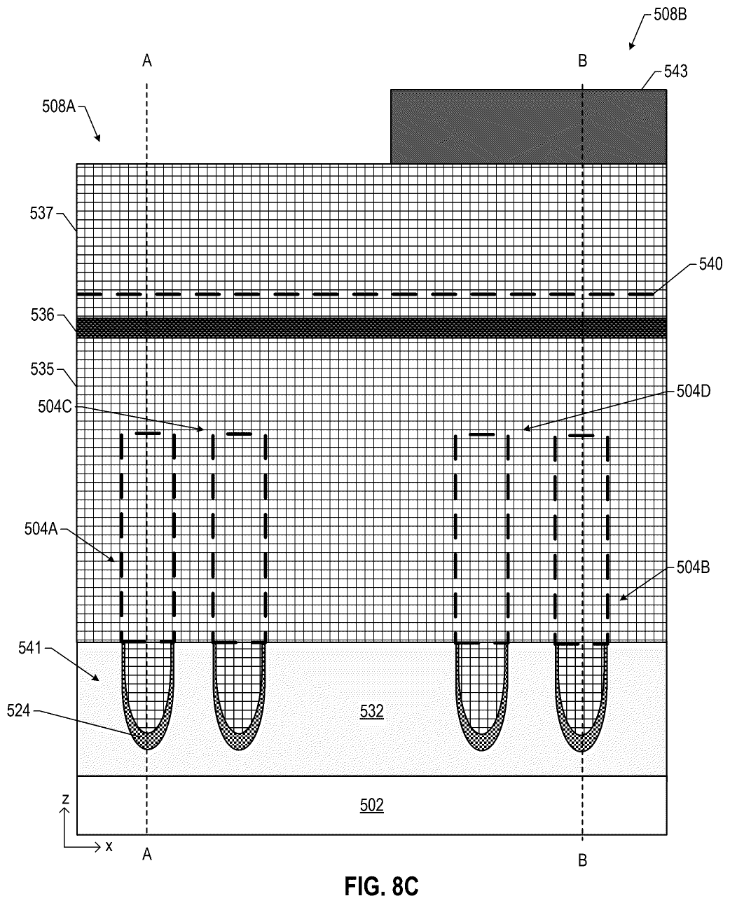

FIGS. 5A-14C provide cross-sectional side views at various stages in the fabrication of an example IC structure according to the method of FIG. 4, in accordance with some embodiments. FIGS. 5-14 include figures labeled with letters A and B (e.g., FIG. 5 includes FIGS. 5A and 5B), providing cross-section views of different portions of an IC structure. In particular, those figures of FIGS. 5-14 labeled with a letter A (e.g., FIG. 5A) illustrate a cross-sectional view of a portion of the IC structure showing elements of a first pair of adjacent nanoribbon transistors in a first nanoribbon stack in the y-z plane of the example coordinate system shown in FIG. 1. Those figures of FIGS. 5-14 labeled with a letter B (e.g., 5B) illustrate a cross-sectional view of another portion of the IC structure showing elements of a second pair of adjacent nanoribbon transistors in a second nanoribbon stack in the y-z plane. In one example, those figures of FIGS. 5-14 labeled with a letter A may show elements of one type of transistor (e.g., an NMOS transistor), while those figures labeled with a letter B may show elements of another type of transistor (e.g., a PMOS transistor), or vice versa. Some of FIGS. 5-14 (e.g., FIGS. 8-14) also include a third figure labeled with a letter C. Those figures of FIGS. 8-14 labeled with a letter C show a different cross-sectional view of the IC structure from the x-z plane of the example coordinate system shown in FIG. 1.

Turning to FIG. 4, the method 400 begins with a process 402 of providing a preliminary IC structure including one or more stacks of nanoribbons and S/D regions in the one or more stacks of nanoribbons. The method continues with the process 404 of forming a first opening between a first S/D region and a second S/D region and the process 406 of forming a second opening between a third S/D region and a fourth S/D region. IC structures 505A and 505B of FIGS. 5A-5B illustrate an example result of the processes 402, 404, and 406. As can be seen in FIG. 5A, the preliminary IC structure 505A includes a stack 504A of nanoribbons over a support 502. Similarly, the IC structure 505B of FIG. 5B includes a stack 504B of nanoribbons over a support 502. In one example, the IC structures 505A and 505B shown in FIGS. 5A-5B may be different portions of the same nanoribbon stack, or portions of two different nanoribbon stacks.

In one example, the IC structures 505A and 505B include features of transistors similar to the transistor 110 but built on the basis of a stack of a plurality of nanoribbons (e.g., built on the basis of the nanoribbon stacks 504A, 504B) instead of just one nanoribbon as shown in FIG. 1. In one example, portions of the nanoribbon stacks 504A, 504B are channel regions of transistors. For example, referring to FIG. 5A, the portions 503-1 of the nanoribbon stack 504A are channel regions of a first transistor, and the portions 503-2 of the nanoribbon stack 504B are channel regions of a second transistor. Similarly, referring to FIG. 5B, the portions 503-3 of the nanoribbon stack 504B are channel regions of a third transistor, and the portions 503-4 of the nanoribbon stack 504B are channel regions of a fourth transistor. While four nanoribbons are shown to be included in each of the nanoribbon stacks 504A, 504B, in other embodiments, fewer nanoribbons or more nanoribbons may be included. FIGS. 5A and 5B illustrate a semiconductor material 532 as the material of the nanoribbons of the stacks 504A, 504B, further illustrating subfins 542A, 542B of the semiconductor material 532 below the respective nanoribbon stacks 504A, 504B, although in some embodiments the nanoribbons and at least a portion of the subfins 542A, 542B may include materials of different compositions. FIGS. 5A-5B illustrate a material 546 over the stacks 504A, 504B of nanoribbons, which may be a dummy gate or replacement gate provided around the fin. In one example, the material 546 may be any suitable material such as polysilicon.

The nanoribbon stacks 504A, 504B may be formed by providing a stack of alternate layers of the semiconductor material 532 and another material 534 (e.g., another semiconductor material) and forming fins from the stack. The semiconductor material 532 may be any of the semiconductor/channel materials described above with reference to the nanoribbon 104 of FIG. 1. The material 534 may be any suitable material that is etch-selective with respect to the semiconductor material 532 so that, in a later process, the material 534 may be etched away to form nanoribbons of the semiconductor material 532. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the semiconductor material 532 may be silicon while the material 534 may be a second semiconductor material such as silicon germanium. In another example, the semiconductor material 532 may be silicon germanium, while the material 534 may be silicon. In other examples, the material 534 may be made of a non-semiconductor material, e.g., of an insulator material, as long as this material is sufficiently etch-selective with respect to the semiconductor material 532.

Thus, the material 534 may be any suitable sacrificial material that is etch-selective with respect to the semiconductor material 532. Selecting the material 534 to be a semiconductor material may be particularly advantageous because it may improve quality of the semiconductor material 532 if the semiconductor material 532 is epitaxially grown on the material 534. In some embodiments, the process may include epitaxially growing layers of the semiconductor material 532 and the material 534 (e.g., another semiconductor material) in an alternating manner. In other embodiments, alternate layers of the semiconductor material 532 and the material 534 may be provided in the process using other techniques, such as layer transfer or thin-film deposition. Although FIG. 5A illustrates the same semiconductor material 532 in various layers of the IC structures 505A, 505B, in general, material compositions of a semiconductor material from which nanoribbons will later be formed in different layers of the IC structures 505A, 505B may be different. For example, the semiconductor material 532 of one layer of the IC structure 505A may be silicon while the semiconductor material 532 of another layer of the IC structure 505A may be a III-N semiconductor material such as GaN. Although the nanoribbons of the stacks 504A and 504B are shown to include the same semiconductor material 532, in other examples, the nanoribbon stack 504A may include nanoribbons of a different semiconductor material than the nanoribbon stack 504B. Also, although the stacks 504A, 504B illustrated in FIGS. 5A-5B include the same number of nanoribbons, which are shown as having the same thickness, in other examples, different stacks of an IC structure may include different numbers of nanoribbons, which may have the same or different thicknesses.

FIGS. 5A and 5B further illustrate S/D regions extending through the nanoribbon stacks 504A, 504B. Specifically, FIG. 5A illustrates S/D regions 514A-1 and 514A-2 for a first transistor, and S/D regions 514A-3 and 514A-4 for a second transistor. Similarly, FIG. 5B illustrates S/D regions 514B-1 and 514B-2 for a third transistor, and S/D regions 514B-3 and 514B-4 for a fourth transistor. The S/D regions 514A-1-514A-4 and 514B-1-514B-4 may be referred to herein as “S/D regions 514.” Referring to FIGS. 5A-5B, in one example, the S/D regions 514 include a semiconductor material 568 (e.g., a doped semiconductor material) in S/D openings formed in the stacks 504A, 504B. Although the S/D regions 514 are depicted as including the same semiconductor material 568, the S/D regions 514 may include the same semiconductor material or a different semiconductor material. In the example illustrated in FIGS. 5A-5B, prior to providing the semiconductor material 568 in the openings, the material 534 was recessed away from the original side walls of the S/D openings to form “dimples” 560 on sidewalls of the S/D openings. In the example illustrated in FIGS. 5A-5B, the IC structures 505A, 505B include a spacer or insulator material 566 in the dimples 560, which can separate the S/D regions 514 from the gate electrode material that is provided in a later process. The insulator material 566 may also line bottoms of the openings (e.g., in the subfins 542A, 542B), as shown in FIGS. 5A-5B. The insulator material 566 may include any of the insulator materials described herein, e.g., any of the ILD materials described above.

In the examples illustrated in FIGS. 5A-5B, the IC structures 505A, 505B include an insulator material 520 in S/D contact openings. The insulator material 520 may be, for example, silicon oxide or any suitable insulator material. The insulator material 520 may be removed from over one or more of the S/D regions 514 in a later process in order to provide S/D contact structures. The S/D contact openings may also include one or more liners on sidewalls of the openings, such as the liner 556. In one example, the liner 556 may be the same as, or similar to, the gate spacers 308 or the liners 310 described with reference to FIGS. 3A and 3B above. The IC structures 505A, 505B also include an insulator material 522 over the dummy gate material 546. The insulator material 522 may be any suitable insulator material, such as silicon nitride, or another insulator material such as those described above.

The IC structures 505A, 505B also include one or more mask layers 524, 526 over the dummy gate material 546 and over the S/D regions 514. The mask layers 524, 526 cover the S/D regions 514 and channel region portions 503-1-503-4 of the IC structures 505A, 505B, and have openings in regions between the S/D regions 514 of adjacent transistors (e.g., in regions between the S/D regions 514A-2 and 514A-3, and between the S/D regions 514B-2 and 514B-3). The mask layers 524, 526 may include any suitable mask material such as hard mask materials (e.g., an oxide or nitride-based hard mask material), or other suitable mask material. Openings 530A, 530B have been formed in the IC structures 505A, 505B through corresponding openings in the mask layers 524, 526. In the examples illustrated in FIGS. 5A, 5B, the openings 530A, 530B are formed between the S/D regions of adjacent transistors. In one example, forming the openings involves etching multiple layers of material including the semiconductor material 532 of the nanoribbon stacks 504A, 504B. Any suitable etching technique, e.g., a dry etch, such as e.g., radio frequency (RF) reactive ion etch (RIE) or inductively coupled plasma (ICP) RIE may be used form the openings 530A, 530B. In some embodiments, the etch performed in the processes 404 and 406 may include an anisotropic etch, using etchants in a form of e.g., chemically active ionized gas (i.e., plasma) using e.g., bromine (Br) and chloride (CI) based chemistries. In some embodiments, during the etch of the processes 404, 406, the IC structure may be heated to elevated temperatures, e.g., to temperatures between about room temperature and 200 degrees Celsius, including all values and ranges therein, to promote that byproducts of the etch are made sufficiently volatile to be removed from the surface. In the example illustrated in FIGS. 5A, 5B, forming the openings involves etching the portions of the nanoribbons of the stacks 504A, 504B between the S/D regions of adjacent transistors. In one example, the depth of the openings extends into the subfin, and may extend further than the adjacent S/D regions 514.

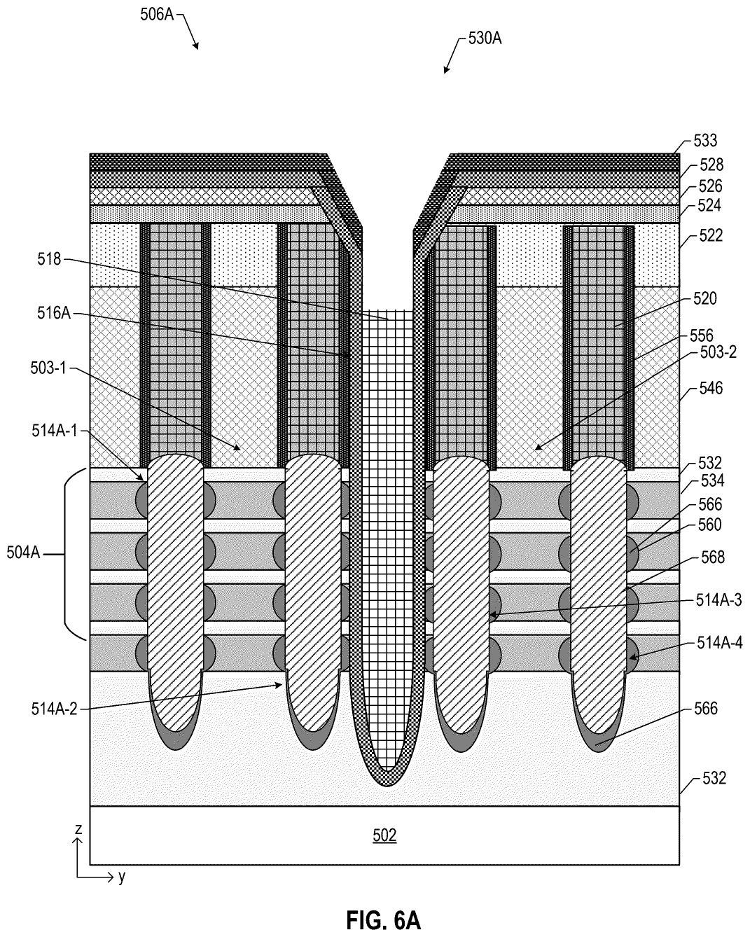

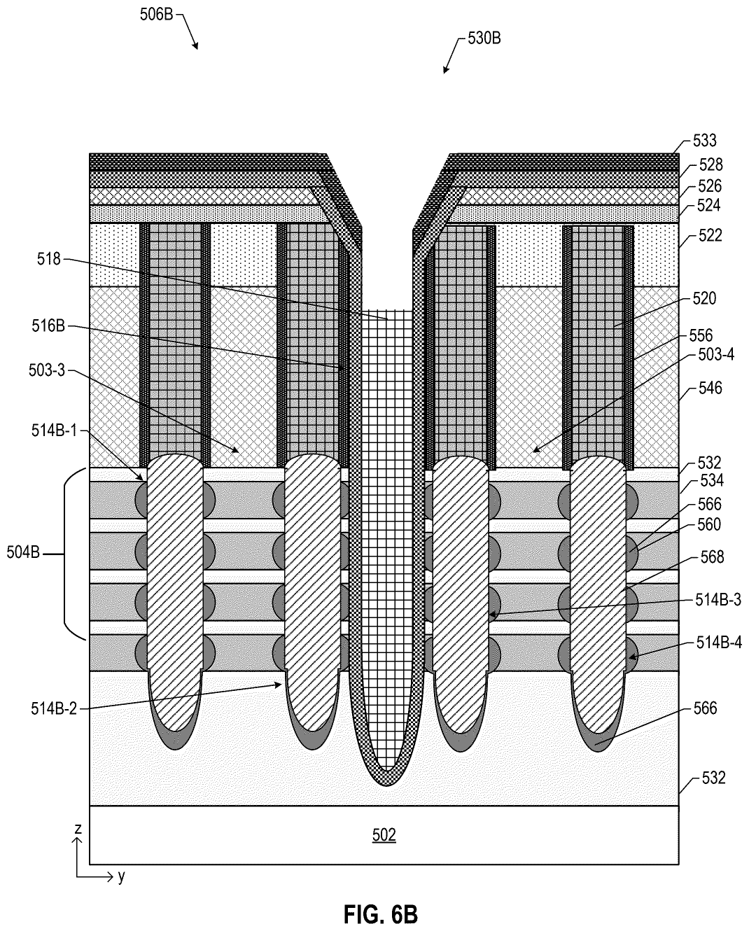

The method 400 continues with the process 408 of providing one or more liners on sidewalls of the first and second openings. FIGS. 5A, 5B illustrate one liner 528 on sidewalls 516A, 516B of respective openings 530A, 530B. In one example, the liner 528 includes a conformal barrier layer that prevents materials deposited into the openings 530A, 530B from encroaching into materials adjacent to the openings 530A, 530B. In the example illustrated in FIGS. 5A, 5B, the liner 528 is also present at the bottoms of the openings 530A, 530B (e.g., lining the portions of the openings 530A, 530B in the subfins 542A, 542B) and over the mask layers 524, 526. In one example, the liner 528 includes an insulator material and may include one or more of silicon, oxide, carbon, and nitride. In one such example, the liner 528 includes SiOCN. Other liner materials are also possible on sidewalls of the openings 530A, 530B. FIGS. 6A, 6B illustrate a second liner 533 that is provided on top portions of the sidewalls 516A, 516B and over the mask layers 524, 526. In one example, the liner 533 includes a material for protecting the underlying materials from damage from subsequent etch processes. In one example, the liner 533 includes titanium nitride (TiN) or another suitable material to act as a hard mask and/or barrier layer to protect underlying materials.

Referring again to FIG. 4, the method 400 continues with the process 410 of providing a sacrificial material in the first and second openings. The IC structure 506A of FIG. 6A and the IC structure 506B of FIG. 6B illustrate an example result of the process 410. As can be seen in FIGS. 6A and 6B, a sacrificial material 518 has been provided in the openings 530A, 530B. The sacrificial material 518 may include any suitable material to be removed from the openings 530A, 530B in a later process. In one example, the sacrificial material 518 may include a carbon-based material, such as a carbon-based hard mask material. In one such example, the sacrificial material 518 includes a high temperature carbon hard mask. In one example, providing the sacrificial material may involve depositing the sacrificial material 518 (e.g., with a spin-on deposition process or other suitable deposition technique) such that it completely fills the openings 530A, 530B, and then recessing the sacrificial material 518 in the openings 530A, 530B. In one example, the sacrificial material 518 is recessed to below the insulator material 522. Thus, in the example in FIGS. 6A, 6B, a continuous volume of the sacrificial material 518 fills the openings 530A, 530B from the bottoms of the openings 530A, 530B to a layer above the S/D regions 514 and above the channel region portions 503-1-503-4 of the nanoribbons.

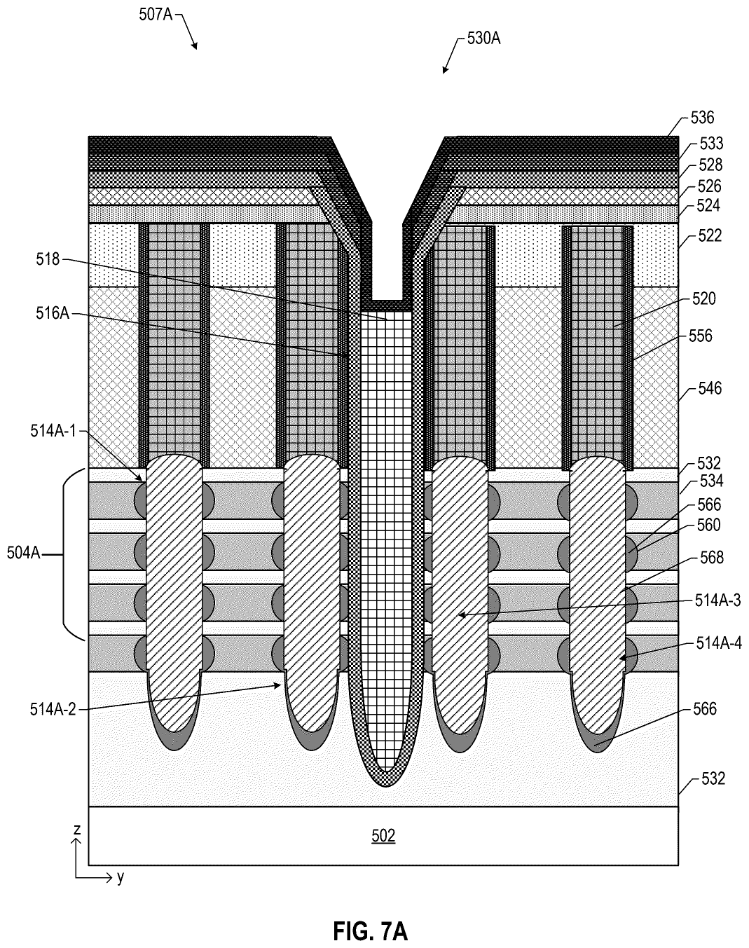

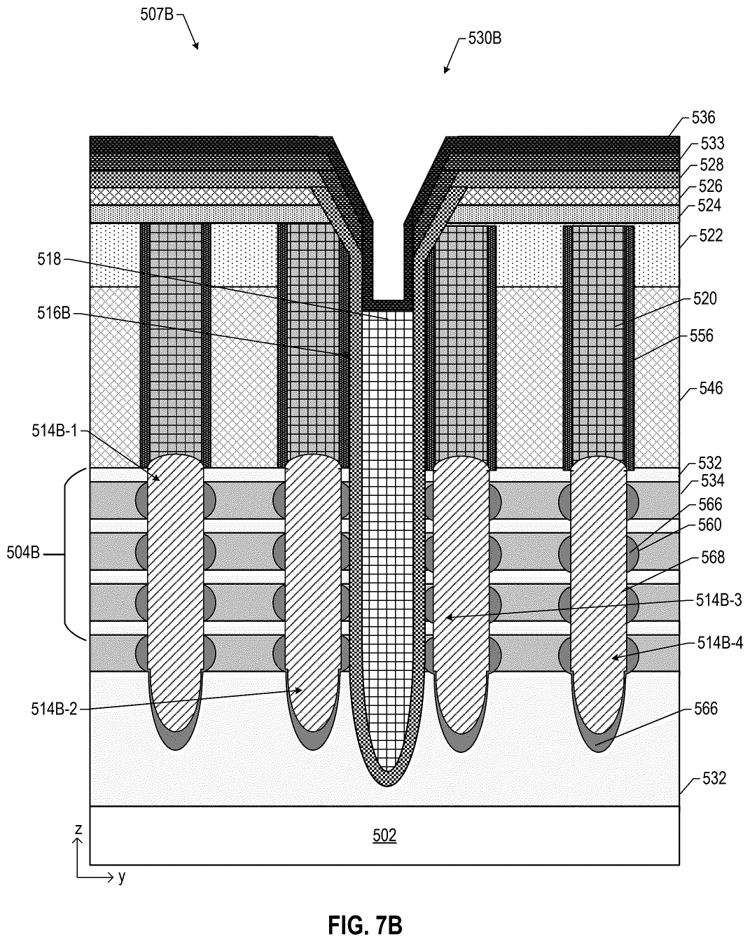

In one example, after filling the openings 530A, 530B with a sacrificial material and recessing the material to the desired height within the openings 530A, 530B. The method may involve providing an etch stop layer over the recessed sacrificial material 518 in the openings 530A, 530B. An IC structure 507A of FIG. 7A and an IC structure 507B of FIG. 7B illustrate an example result of the process of providing an etch stop layer over the sacrificial material. As can be seen in FIGS. 7A, 7B, the IC structures 507A, 507B include a conformal layer of an etch stop material 536 over the sacrificial material 518 in the openings 530A, 530B, as well as on exposed sidewalls 516A, 516B of the openings 530A, 530B. In the example illustrated in FIGS. 7A, 7B, the etch stop material 536 is also present over the layers 524, 526, and over the liners 528, 533 above the S/D regions 514 and channel regions.

After providing the etch stop layer over the sacrificial material 518 in the openings 530A, 530B, one or more additional materials may be provided over the etch stop material 536 to enable removal of the sacrificial material from one of the openings 530A, 530B. For example, referring again to FIG. 4, the method 400 continues with the process 412 of providing a mask layer over the preliminary IC structure that covers the second opening. IC structures 508A, 508B of FIGS. 8A-8C illustrate an example result of the process 412. As mentioned above, FIGS. 8A-8C illustrate different cross-sectional views of the same IC structure. FIGS. 8A and 8B illustrate cross-sectional views of different nanoribbon stacks along the y-z plane. FIG. 8C illustrates a different cross-sectional view along the x-z plane. Specifically, FIG. 8C illustrates a cross-section along a plane CC shown in FIGS. 8A and 8B.

As can be seen in FIGS. 8A and 8B, an additional layer 537 of the sacrificial material 518 has been provided over the etch stop material 536 in the openings 530A and 530B. Additionally, a mask layer 543 has been provided over the IC structure that covers the opening 530B and which has an opening over the opening 530A. In one example, the mask layer 543 may include a photoresist material or any other suitable mask material. Although not specifically shown, one or more additional layers of materials may be present over the layer 537 of the sacrificial material 518.

Referring to FIG. 8C, a cross-sectional view along the x-z axis can be seen of the nanoribbon stacks 504A and 504B, as well as two other nanoribbon stacks 504C, 504D. Although the cross-sectional view in FIG. 8C does not depict the nanoribbons of the nanoribbon stacks 504A-504D, the approximate outlines of the nanoribbon stacks 504A-504D are depicted with dashed boxes. As can be seen in FIG. 8C, the mask layer 543 is present over the nanoribbon stack 504B, and absent over the nanoribbon stack 504A. The dashed line 540 depicts the approximate top of the material 546 shown in FIGS. 8A-8B.

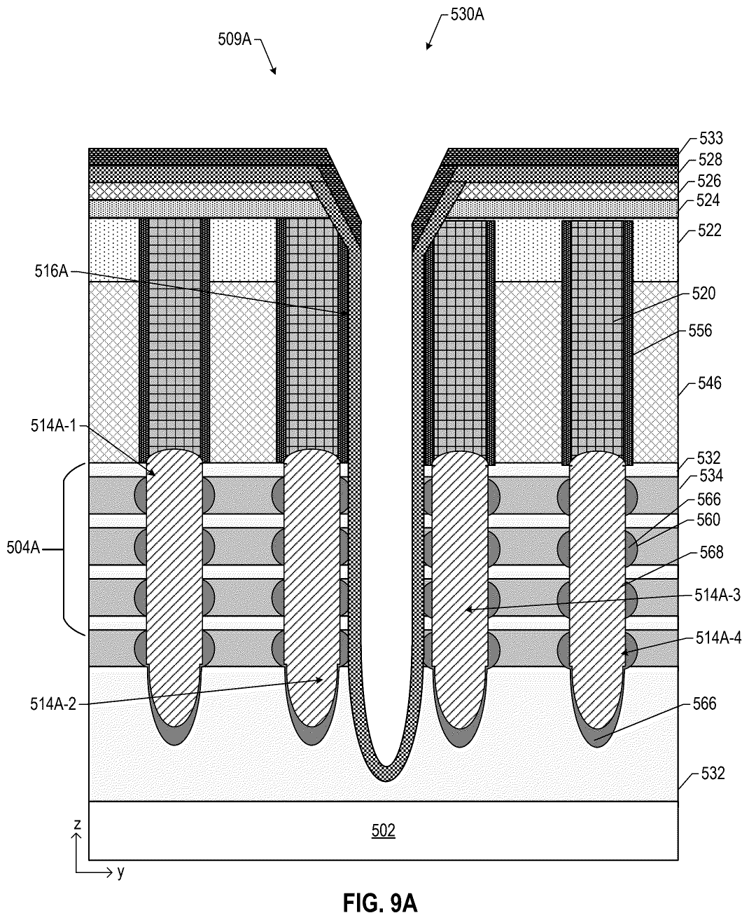

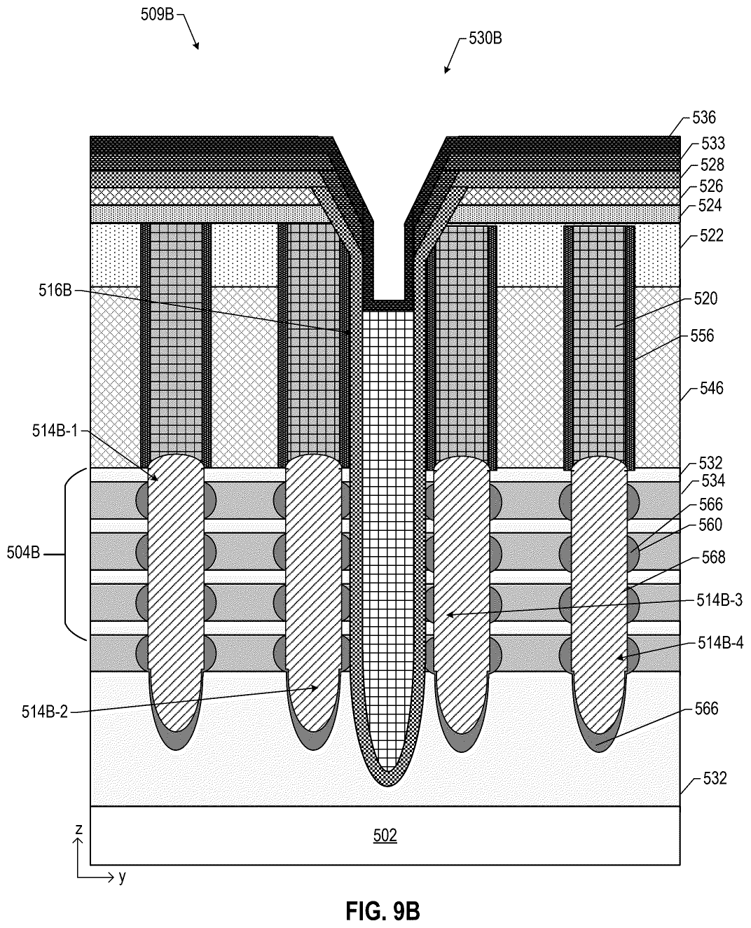

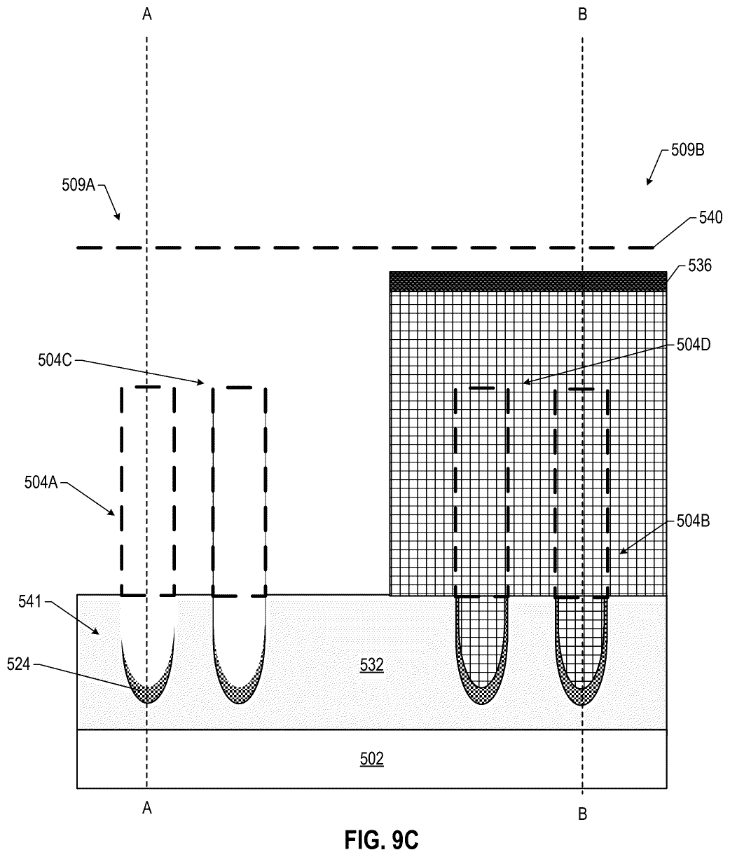

Referring again to FIG. 4, the method 400 continues with the process 414 of removing the sacrificial material from the first opening. IC structures 509A, 509B of FIGS. 9A-9C illustrate an example result of the process 414. As can be seen in FIGS. 9A-9C, the sacrificial material 518 has been removed from the opening 530A, exposing the liner 528 on sidewalls 516A of the opening 530A. The sacrificial material 518 has not been removed from the opening 530B. In one example, removing the sacrificial material 518 from the first opening 530A involves etching the layer 537 of the sacrificial material from over the first opening 530A, but not from over the second opening 530B due to the presence of the mask. The etch stop material 536 may then be etched from over the first opening 530A, and the mask layer 543 may be removed from over the second opening 530B. The sacrificial material 518 may then be removed from within the opening 530A. In one such example, the layer 537 of the sacrificial material over the second opening 530B may also be removed with the same process that removes the sacrificial material 518 from within the first opening 530A. In one example in which the sacrificial material 518 is a carbon hard mask, the sacrificial material 518 may be removed from the first opening 530A with an ashing process. Thus, the process of removing the sacrificial material 518 results in removing the sacrificial material 518 from the opening 530A (e.g., from within the first opening 530A including from the bottom of the opening 530A), while stopping on the etch stop material 536 over the second opening 530B. The first opening 530A may then be selectively filled with one or more materials in a subsequent process without filling the bottom of the second opening 530B.

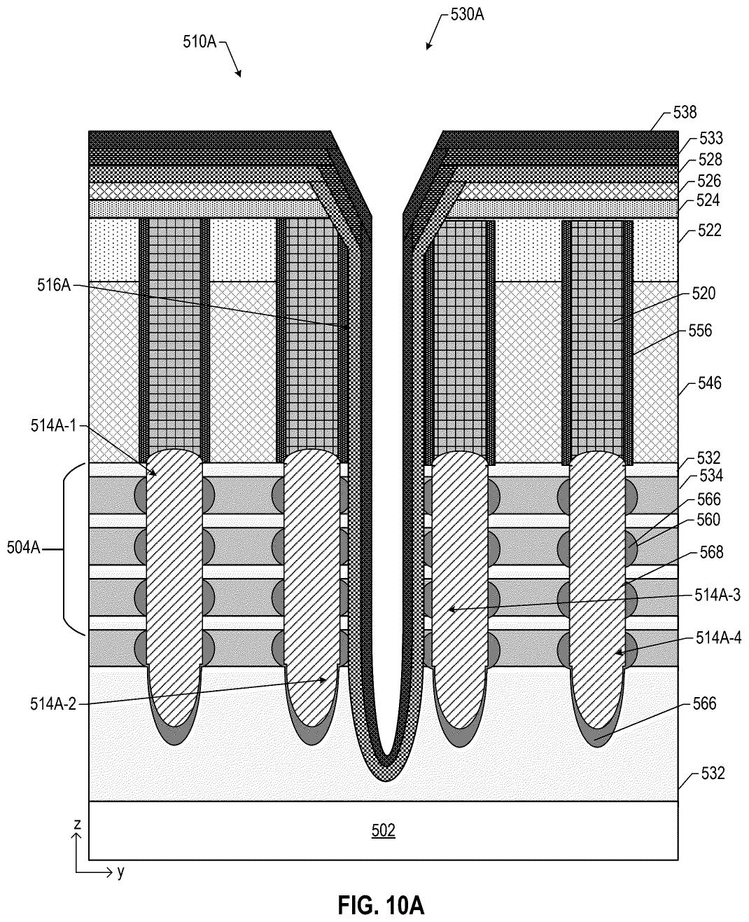

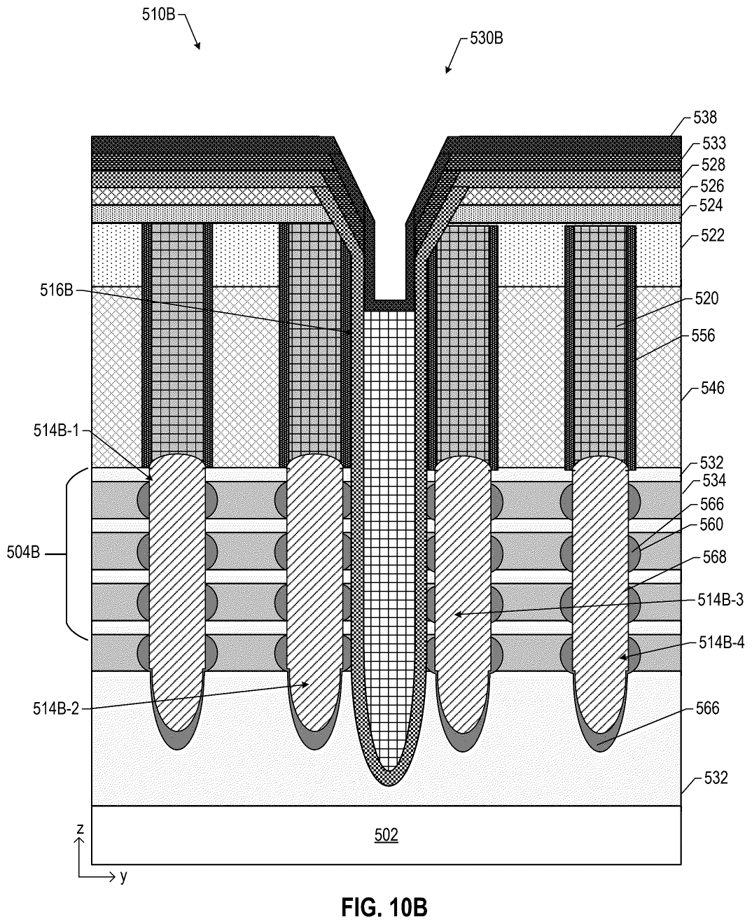

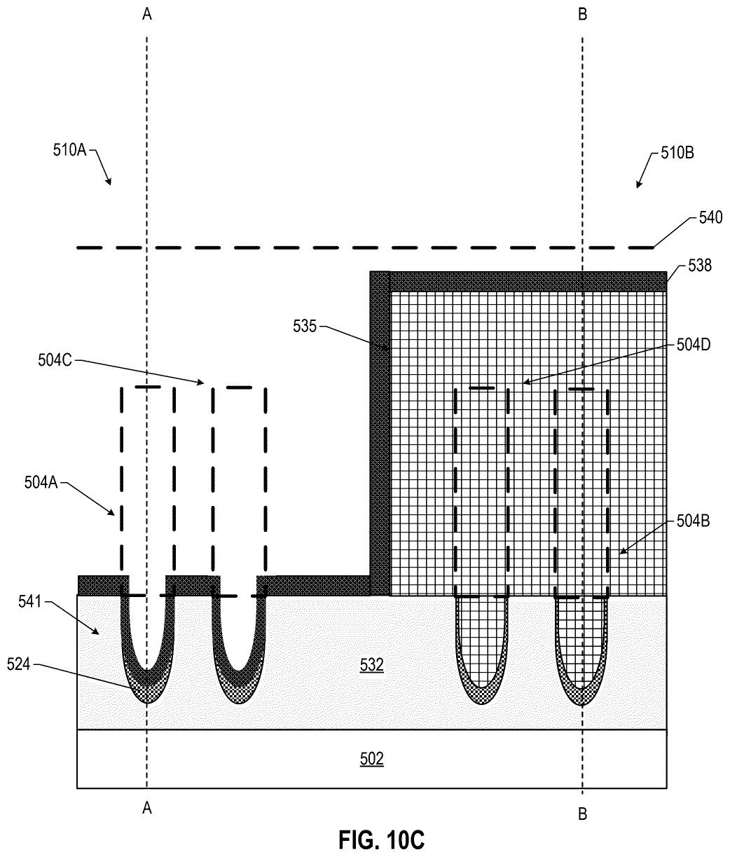

After removing the sacrificial material 518 from the first opening, the method may involve providing an adhesion layer on sidewalls of the first opening 530A and on a sidewall of the sacrificial material between adjacent nanoribbon stacks. For example, the IC structures 510A, 510B of FIGS. 10A-10C illustrate an example result of the process of providing an adhesion layer on exposed sidewalls after removing the sacrificial material from the first opening 530A. As can be seen in FIG. 10A, an adhesion layer 538 is present on sidewalls 516A of the opening 530A (e.g., over the liner 528). Referring to FIG. 10B, the adhesion layer 538 is also shown on exposed sidewalls 516B and over the sacrificial material 518 in the opening 530B. Note that in the example illustrated in FIGS. 10B and 10C, the etch stop material 536 is absent from over the second opening 530B due to removal prior to providing the adhesion layer 538. In one example, the adhesion layer 538 can improve the adhesion of a material to be provided in the first opening 530A to a sidewall 535 of the sacrificial material 518 as seen in FIG. 10C.

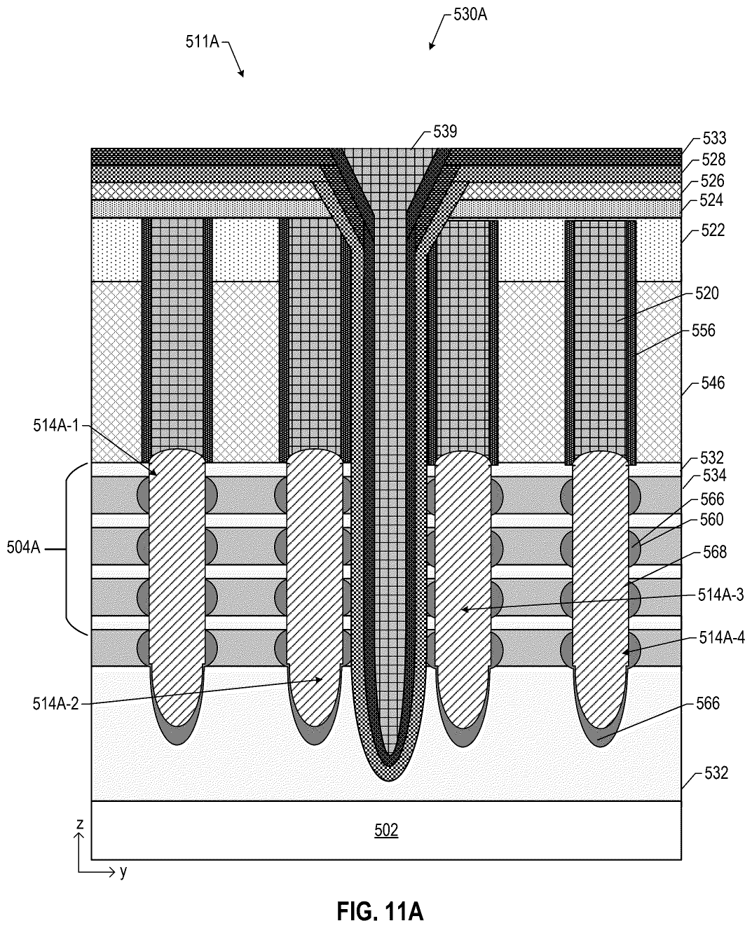

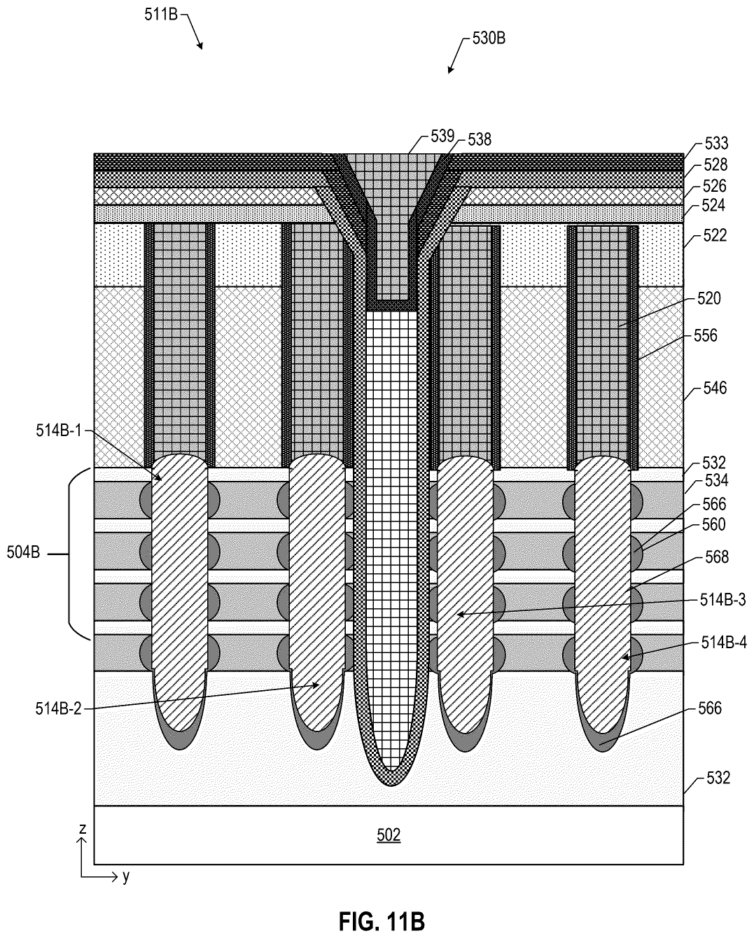

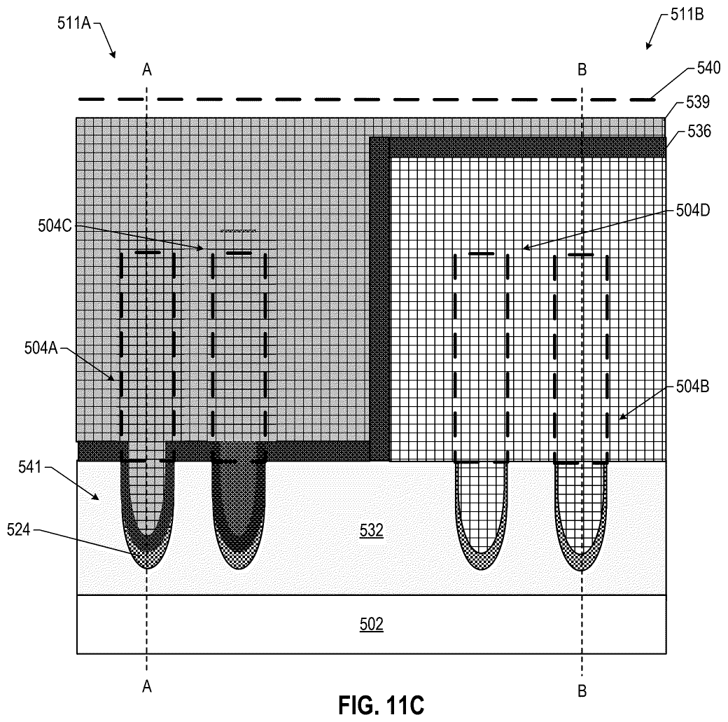

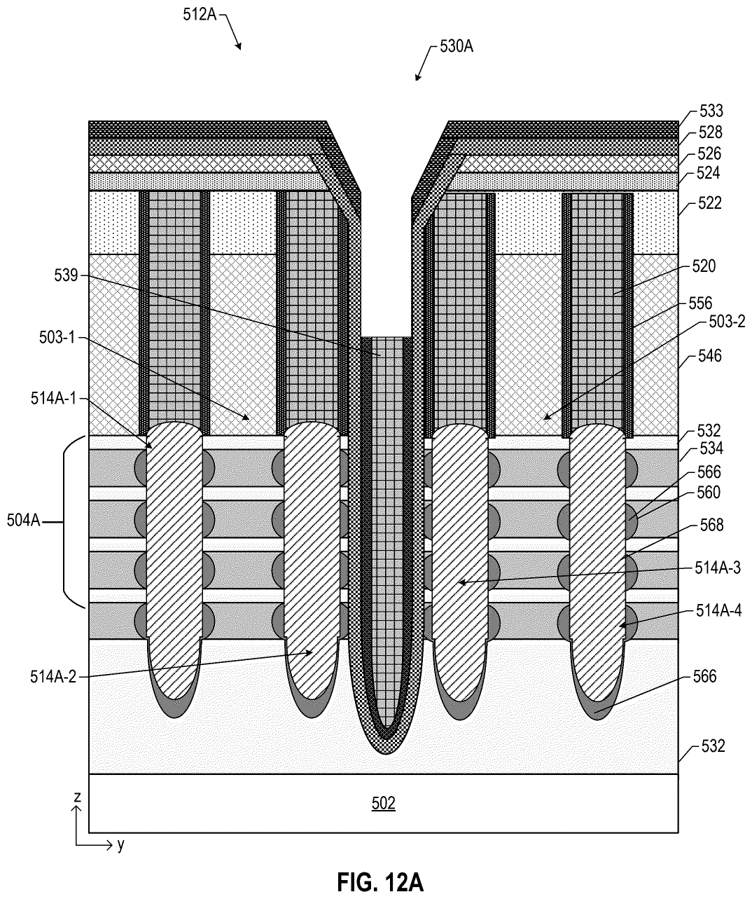

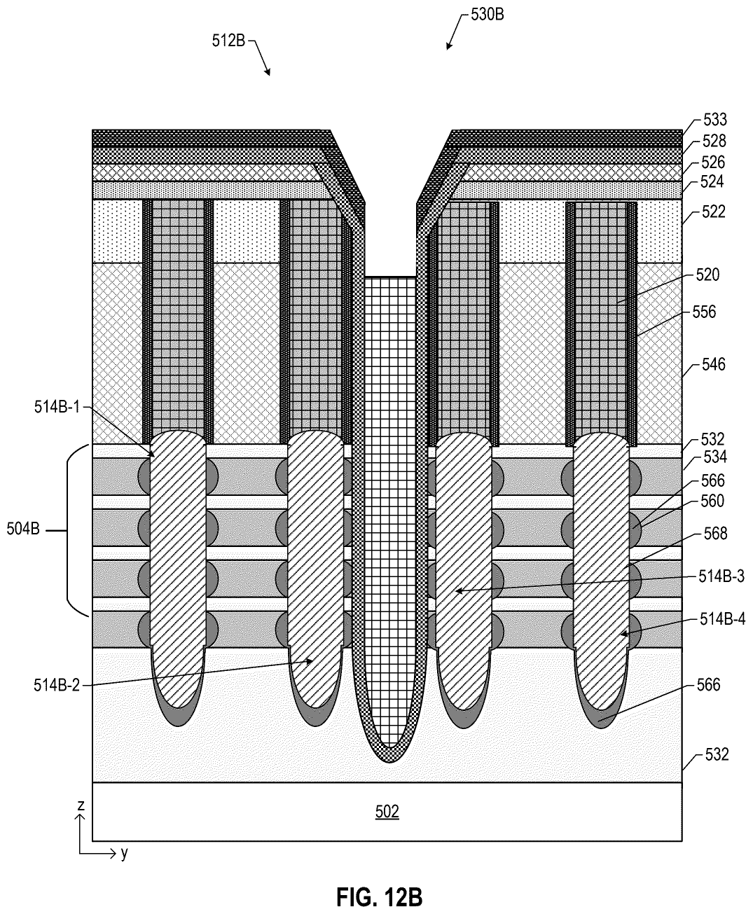

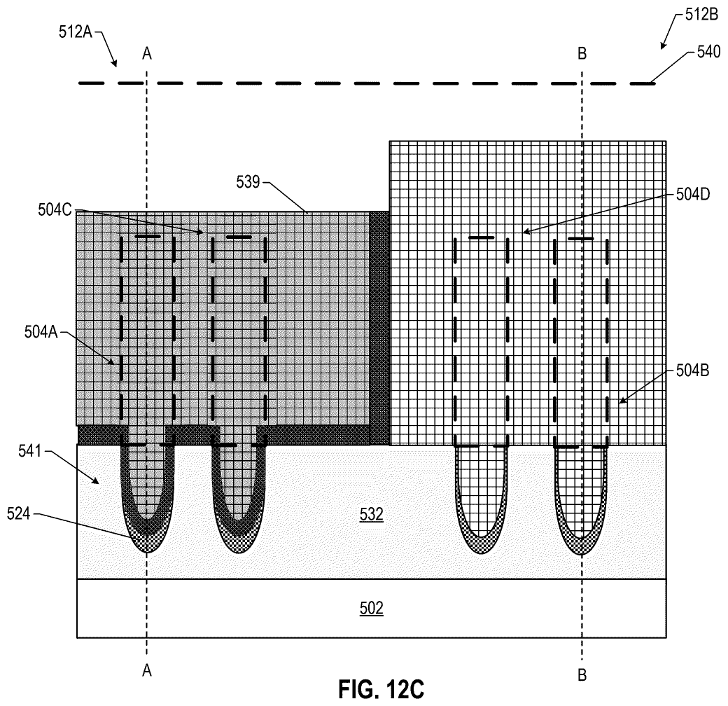

Referring to FIG. 4, the method 400 continues with the process 416 of partially filling the first opening with a first insulator material. Partially filling the first opening with a first insulator material may involve completely filling the opening 530A with a first insulator material and then recessing the first insulator material in the opening 530A. IC structures 511A, 511B of FIGS. 11A-11C illustrate an example result of the process of completely filling the first opening. As can be seen in FIGS. 11A-11C, the opening 530A is filled with a material 539. The insulator material 539 may be any suitable insulator material such as those discussed above. In one example, the insulator material 539 includes silicon oxide. As can be seen in FIG. 11B, the unfilled portion of the opening 530B may also be filled with the insulator material 539. The first insulator material 539 may then be recessed to a desired height in the first opening 530A. IC structures 512A, 512B of FIGS. 12A-12C illustrate an example result of the process of recessing the first insulator material in the first opening. As can be seen in FIG. 12A, the insulator material 539 has been recessed (e.g., via an etch process) in the first opening 530A. The extent to which the insulator material 539 is recessed in the first opening may depend upon the dimensions of other features in the IC structure 512A. In one example, the insulator material 539 is recessed to a layer that is below the insulator material 522 and above the channel region portions 503-1, 503-2. In one such example the insulator material 539 in the opening 530A can thus cause a desired strain on the resulting adjacent devices. In one example, the insulator material 539 is also removed from the second opening 530B. In the example illustrated in FIG. 12B, the etch stop material 536 has also been removed from the second opening 530B. In one such example, the same etch process or a different etch process may be used to recess the first insulator material 539 in the first opening 530A and remove the etch stop material 536.

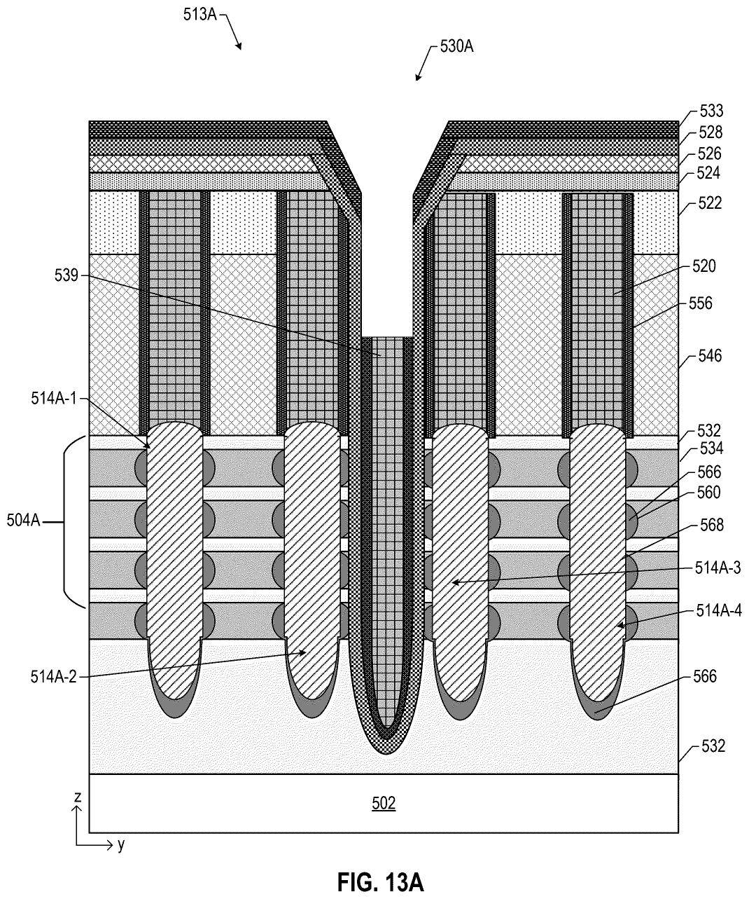

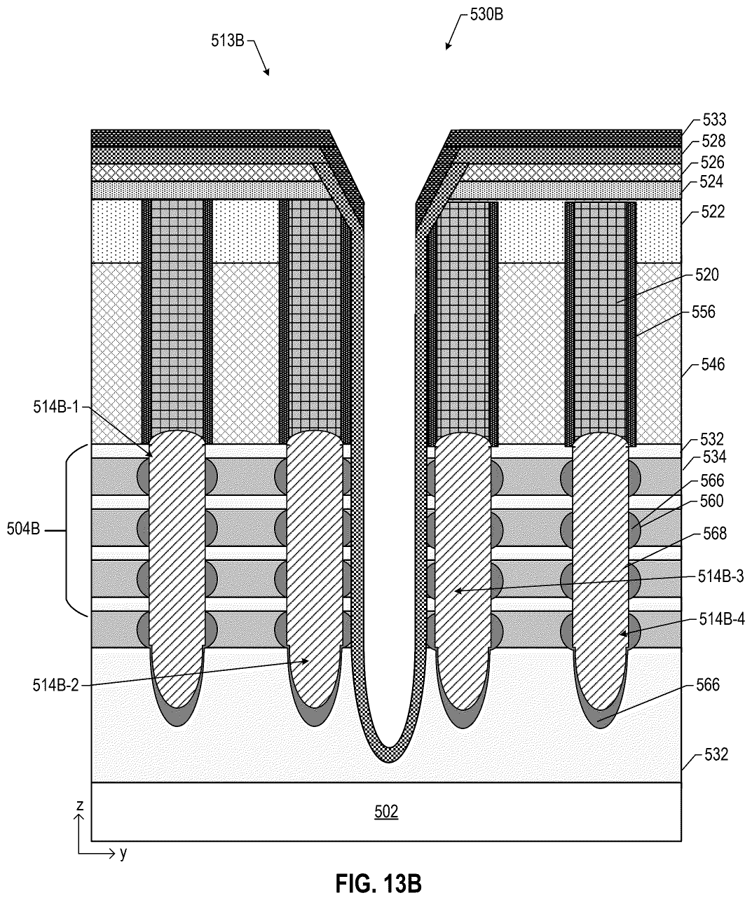

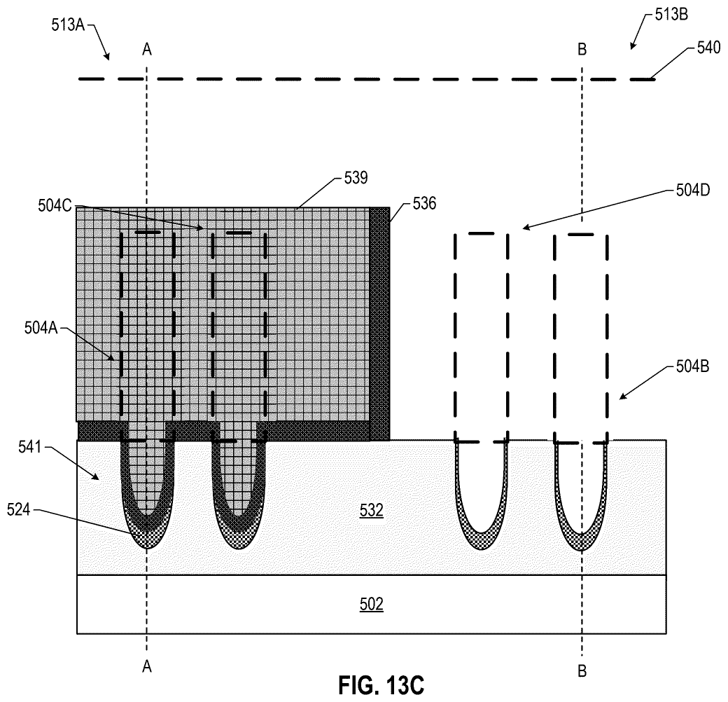

Referring to FIG. 4, the method 400 continues with the process 418 of removing the sacrificial material from the second opening. IC structures 513A, 513B of FIGS. 13A-13C illustrate an example result of the process 418. As can be seen in FIGS. 13B and 13C, the sacrificial material 518 has been removed from the second opening 530B. Removing the sacrificial material 518 from the second opening 530B may involve the same or a similar technique as was used for removing the sacrificial material 518 from the first opening 530A, discussed above.

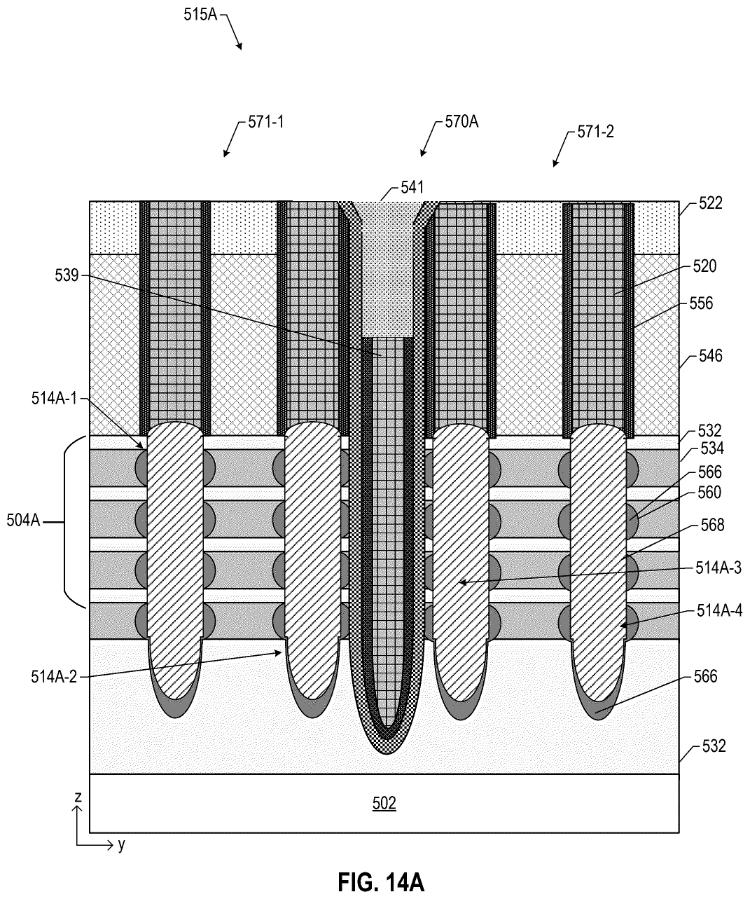

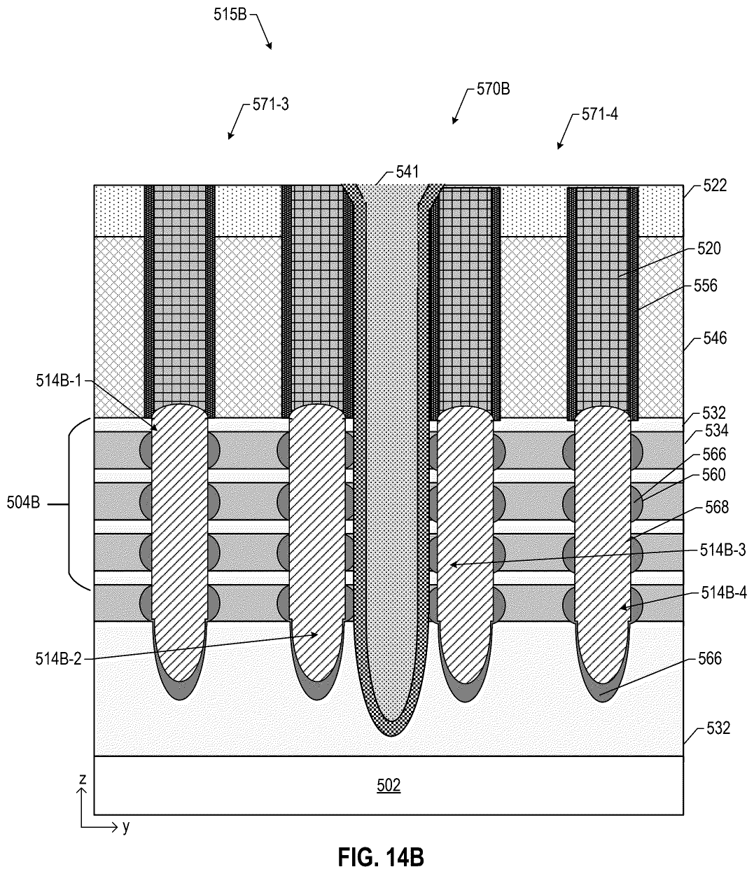

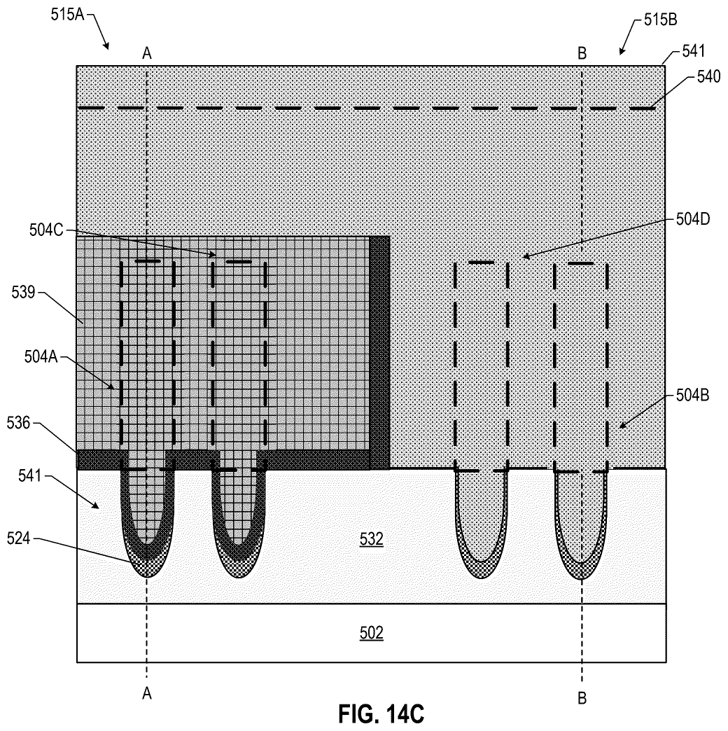

The method 400 continues with the process 420 of filling the second opening with a second insulator material and filling the unfilled portion of the first opening with the second insulator material. IC structures 515A, 515B of FIGS. 14A-14C illustrate an example result of the process 420. As can be seen in FIG. 14A, a second insulator material 541 fills the opening 530A over the first insulator material 539. Turning to FIG. 14B, the opening 530B is completely filled with the second insulator material 541. Filling the first and second openings 530A, 530B with the second insulator material 541 may involve one or more polish and/or etch processes after deposition of the second insulator material 541. In the example illustrated in FIGS. 14A-14C, subsequent polish and/or etch processes result in removal of the liner 533 and the liner 528 from over the mask layers 524, 526 and removal of the mask layers 524, 526. After filling the openings 530A, 530B with the second insulator material, the IC structure may undergo additional processing (e.g., gate replacement processes, contact structure formation processes, etc.) in order to fabricate a resulting IC structure with transistors such as those described herein.

Thus, the method 400 of FIG. 4 is an example method of fabricating an IC structure with differentiated transistor isolation techniques. Performing the method 400 of FIG. 4 may result in features in the final IC structures that are characteristic of the use of the method 400. For example, one such feature is illustrated in the IC structures 300A and 300B of FIGS. 3A-3B and in the IC structures 515A and 515B shown in FIGS. 14A-14C, which show spacer structures between adjacent transistors, where the spacer structures include different materials. For example, FIG. 14A shows a first spacer structure 570A in a first nanoribbon stack portion (e.g., a portion of the nanoribbon stack 504A) electrically isolating a first transistor 571-1 from a second transistor 571-2, where the first spacer structure 570A includes a first insulator material 539 between a first region 514A-2 of a doped semiconductor material and a second region 514A-3 of a doped semiconductor material, and a second insulator material 541 over the first insulator material 539. The IC structure 515B includes a second spacer structure 570B in a second nanoribbon stack portion (e.g., a portion of the nanoribbon stack 504B) electrically isolating a third transistor 571-3 from a fourth transistor 571-4, where the second spacer structure 570B includes the second insulator material 541 between a third region 514B-2 of a doped semiconductor material and a fourth region 514B-3 of a doped semiconductor material. The different materials of the spacer structures can exert different forces (such as tensile or compressive strain) on different pairs of adjacent transistors and/or have other properties to improve device performance.

IC devices/structures fabricated using differentiated transistor isolation techniques as described herein (e.g., as described with reference to FIGS. 1-14C) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC devices disclosed herein, e.g., the IC structures 100, 200, or any variations thereof, may be included in any suitable electronic component. FIGS. 15-18 illustrate various examples of apparatuses that may include any of the IC devices disclosed herein.

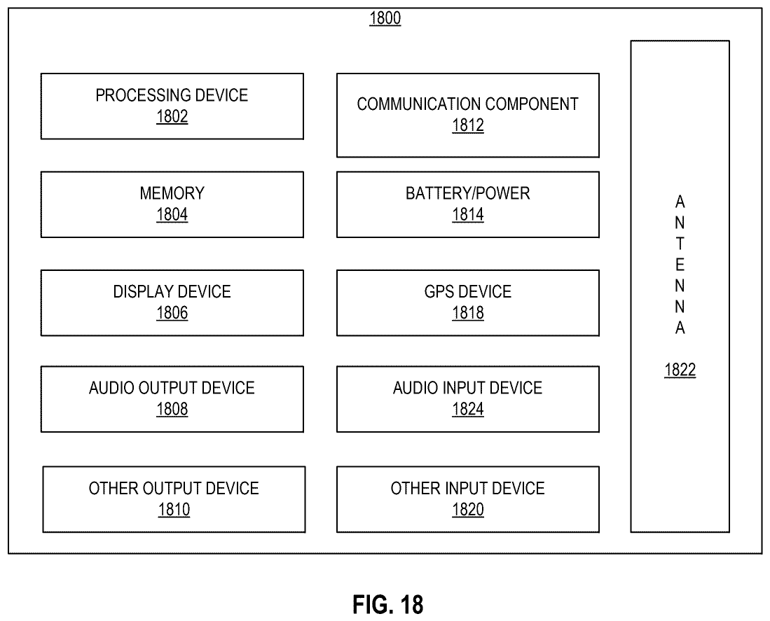

FIG. 15 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC structures 100, 200, described herein), one or more transistors (e.g., nanoribbon transistors of the IC structures 100, 200) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 18) or other logic that is configured to store information in the memory devices or execute instructions stored in the memory array.

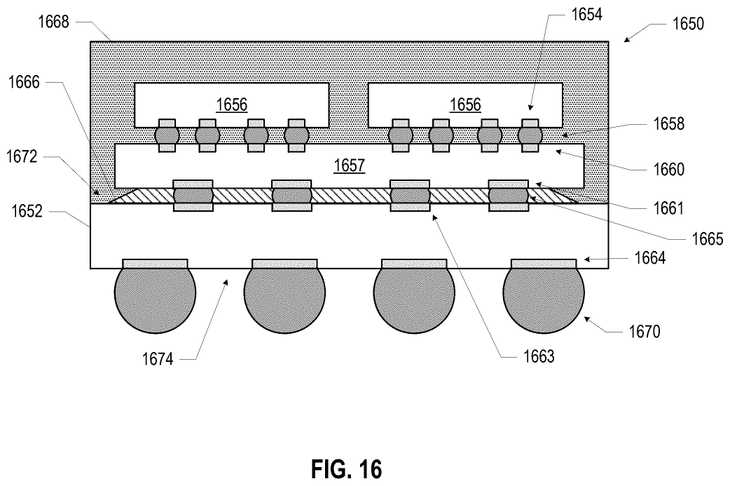

FIG. 16 is a side, cross-sectional view of an example IC package 1650 that may include one or more IC structures in accordance with any of the embodiments disclosed herein (e.g., any of the IC structures 100, 200, described herein). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 16 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 16 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

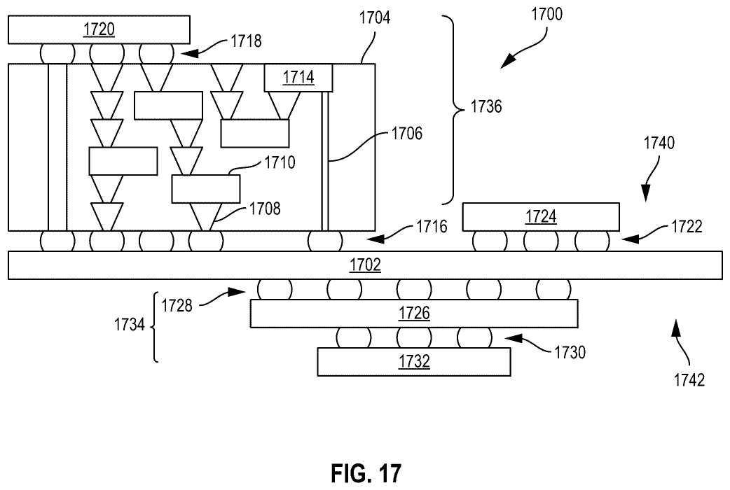

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 16 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 17.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 16 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 16, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 17 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 16 (e.g., may include one or more IC structures 100, 200).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 17 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 17), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 17, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 15), an IC device (e.g., any of the IC structures 100, 200, described herein, or any combination of such IC structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 17, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 17 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 18 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 18 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 18, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including first and second transistors with respective first and second channel regions in first nanoribbons of a first nanoribbon stack; third and fourth transistors with respective third and fourth channel regions in second nanoribbons of a second nanoribbon stack; a first insulator region in the first nanoribbon stack between the first and second transistors, where the first insulator region includes a first insulator material in a first layer with the first and second channel regions and a second insulator material in a second layer that is over the first layer, where the first insulator material has a different material composition than the second insulator material; and a second insulator region in the second nanoribbon stack between the third and fourth transistors, where the second insulator region includes the second insulator material in the first layer and in the second layer.

Example 2 provides the IC structure of example 1, further including a third insulator material on first sidewalls of the first insulator region and on second sidewalls of the second insulator region.

Example 3 provides the IC structure of example 2, where: the first insulator region includes a fourth insulator material between the first insulator material and the third insulator material.

Example 4 provides the IC structure of example 3, where: the second insulator region lacks the fourth insulator material between the second insulator material and the third insulator material.

Example 5 provides the IC structure of examples 3 or 4, where: the first nanoribbon stack is adjacent to the second nanoribbon stack; where the first insulator region and the second insulator region are in a same plane that is perpendicular to the first nanoribbons; and the IC structure includes the fourth insulator material between and in contact with the first insulator material of the first insulator region and the second insulator material of the second insulator region.

Example 6 provides the IC structure of any one of examples 4-6, where: the fourth insulator material is present at a bottom of the first insulator region; and the fourth insulator material is absent from a bottom of the second insulator region.

Example 7 provides the IC structure of any one of examples 1-6, where: the first insulator region includes a continuous portion of the first insulator material in a first plane below a first source or drain region of the first and second transistors, and a continuous portion of the second insulator material in contact with the continuous portion of the first insulator material, where the continuous portion of the second insulator material is in a second plane above the first source or drain region; and the second insulator region includes a second continuous portion of the second insulator material in the first plane and in the second plane.

Example 8 provides the IC structure of example 7, where: the continuous portion of the second insulator material of the first insulator region is in a same layer as a contact structure of the first transistor.

Example 9 provides the IC structure of any one of examples 1-8, where: the first insulator region includes a first volume of the first insulator material and a second volume of the second insulator material; and a ratio of the first volume to the second volume is in a range of about 1:1 to 1:9.

Example 10 provides the IC structure of any one of examples 1-9, where: the first and second transistors are NMOS transistors; and the third and fourth transistors are PMOS transistors.

Example 11 provides an integrated circuit (IC) structure, including one or more stacks of nanoribbons, where the one or more stacks of nanoribbons include a first nanoribbon stack portion and a second nanoribbon stack portion; a first spacer structure in the first nanoribbon stack portion electrically isolating a first transistor from a second transistor, where the first spacer structure includes a first insulator material between a first region of a doped semiconductor material of the first transistor and a second region of a doped semiconductor material of the second transistor, and a second insulator material over the first insulator material; and a second spacer structure in the second nanoribbon stack portion electrically isolating a third transistor from a fourth transistor, where the second spacer structure includes the second insulator material between a third region of a doped semiconductor material of the third transistor and a fourth region of a doped semiconductor material of the fourth transistor.

Example 12 provides the IC structure of example 11, where: the first insulator material has one or more different material properties from the second insulator material, including one or more of: material composition, density, and dielectric constant.

Example 13 provides the IC structure of any one of examples 11-12, further including a barrier layer on first sidewalls of the first spacer structure and on second sidewalls of the second spacer structure.

Example 14 provides the IC structure of example 13, where: the first spacer structure includes an adhesion layer between the first insulator material and the barrier layer.

Example 15 provides the IC structure of example 14, where: the adhesion layer is absent between the second insulator material of the second spacer structure and the barrier layer.

Example 16 provides the IC structure of any one of examples 14-15, where: the adhesion layer is present at a bottom of the first spacer structure; and the adhesion layer is absent from a bottom of the second spacer structure.

Example 17 provides the IC structure of any one of examples 11-16, where: the first nanoribbon stack portion and the second nanoribbon stack portion are different portions of a same stack of nanoribbons.

Example 18 provides the IC structure of any one of examples 14-16, where: the first nanoribbon stack portion is in a first nanoribbon stack and the second nanoribbon stack portion is in a second nanoribbon stack adjacent to the first nanoribbon stack; the first spacer structure and the second spacer structure are in a same plane that is perpendicular to a substrate over which the first nanoribbon stack and the second nanoribbon stack are disposed; and the IC structure includes the adhesion layer between and in contact with the first insulator material of the first spacer structure and the second insulator material of the second spacer structure.

Example 19 provides an IC structure according to any one of examples 1-18, where the IC structure includes or is a part of a central processing unit.

Example 20 provides an IC structure according to any one of examples 1-19, where the IC structure includes or is a part of a memory device.

Example 21 provides an IC structure according to any one of examples 1-20, where the IC structure includes or is a part of a logic circuit.

Example 22 provides an IC structure according to any one of examples 1-21, where the IC structure includes or is a part of input/output circuitry.

Example 23 provides an IC structure according to any one of examples 1-22, where the IC structure includes or is a part of a field programmable gate array transceiver.

Example 24 provides an IC structure according to any one of examples 1-23, where the IC structure includes or is a part of a field programmable gate array logic.

Example 25 provides an IC structure according to any one of examples 1-24, where the IC structure includes or is a part of a power delivery circuitry.

Example 26 provides an IC package that includes an IC die including an IC structure according to any one of examples 1-25; and a further IC component, coupled to the IC die.

Example 27 provides an IC package according to example 26 where the further IC component includes a package substrate.

Example 28 provides an IC package according to example 26, where the further IC component includes an interposer.

Example 29 provides an IC package according to example 26, where the further IC component includes a further IC die.

Example 30 provides a computing device that includes a carrier substrate and an IC structure coupled to the carrier substrate, where the IC structure is an IC structure according to any one of examples 1-25, or the IC structure is included in the IC package according to any one of examples 26-29.

Example 31 provides a computing device according to example 30, where the computing device is a wearable or handheld computing device.

Example 32 provides a computing device according to examples 30 or 31, where the computing device further includes one or more communication chips.

Example 33 provides a computing device according to any one of examples 30-32, where the computing device further includes an antenna.

Example 34 provides a computing device according to any one of examples 30-33, where the carrier substrate is a motherboard.

Example 35 provides a method of fabricating an IC structure, the method including providing a preliminary IC structure including one or more stacks of nanoribbons and regions of a doped semiconductor material in the one or more stacks of nanoribbons, the regions including a first region adjacent to a second region and a third region adjacent to a fourth region; forming a first opening between the first region and the second region; forming a second opening between the third region and the fourth region; providing a sacrificial material (e.g., a high temperature carbon hard mask) in the first opening and in the second opening; removing the sacrificial material from the first opening; partially filling the first opening with a first insulator material (e.g., silicon oxide); removing the sacrificial material from the second opening; and filling the second with a second insulator material (e.g., silicon nitride), and filling the first opening with the second insulator material over the first insulator material.

Example 36 provides the method of example 35, further including prior to providing the sacrificial material in the first and second openings, providing one or more liners on sidewalls of the first opening and on sidewalls of the second opening.

Example 37 provides the method of example 36, where: providing one or more liners includes providing a first barrier layer on the sidewalls of the first opening and on the sidewalls of the second opening (e.g., and on the bottom of the openings and on top surface of the IC structure over the mask layer(s)), and providing a second barrier layer on portions (e.g., upper portions) of the sidewalls of the first opening and on portions of the sidewalls of the second opening (e.g., and on the top surface of the IC structure).

Example 37 provides the method of any one of examples 35-36, where: removing the sacrificial material from the first opening includes providing a mask layer over the preliminary IC structure that covers the second opening, and removing the sacrificial material from the second opening with an ashing process.

Example 38 provides the method of any one of examples 35-37, where the sacrificial material is a first layer of the sacrificial material, where the method further includes recessing the first layer of the sacrificial material in the first opening and in the second opening, providing an etch stop layer over the first layer of the sacrificial material in the first opening and in the second opening, and filling the first opening and the second opening with a second layer of the sacrificial material over the etch stop layer.

Example 39 provides the method of example 38, where: removing the sacrificial material from the first opening includes removing the second layer of the sacrificial material from the first opening, removing the etch stop layer over the first layer of the sacrificial material in the first opening, and removing the first layer of the sacrificial material from the first opening.

Example 40 provides the method of any one of examples 35-39, further including after removing the sacrificial material from the first opening, providing an adhesion layer on the sidewalls of the second opening.

Example 41 provides a method according to any one of examples 35-40, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
first and second transistors with respective first and second channel regions in first nanoribbons of a first nanoribbon stack;
third and fourth transistors with respective third and fourth channel regions in second nanoribbons of a second nanoribbon stack;
a first insulator region in the first nanoribbon stack between the first and second transistors, wherein the first insulator region includes a first insulator material in a first layer with the first and second channel regions and a second insulator material in a second layer that is over the first layer, wherein the first insulator material has a different material composition than the second insulator material; and
a second insulator region in the second nanoribbon stack between the third and fourth transistors, wherein the second insulator region includes the second insulator material in the first layer and in the second layer.

2. The IC structure of claim 1, further comprising:
a third insulator material on first sidewalls of the first insulator region and on second sidewalls of the second insulator region.

3. The IC structure of claim 2, wherein:
the first insulator region includes a fourth insulator material between the first insulator material and the third insulator material.

4. The IC structure of claim 3, wherein:
the second insulator region lacks the fourth insulator material between the second insulator material and the third insulator material.

5. The IC structure of claim 3, wherein:
the first nanoribbon stack is adjacent to the second nanoribbon stack;
wherein the first insulator region and the second insulator region are in a same plane that is perpendicular to the first nanoribbons; and
the IC structure includes the fourth insulator material between and in contact with the first insulator material of the first insulator region and the second insulator material of the second insulator region.

6. The IC structure of claim 4, wherein:
the fourth insulator material is present at a bottom of the first insulator region; and
the fourth insulator material is absent from a bottom of the second insulator region.

7. The IC structure of claim 1, wherein:
the first insulator region includes:
a continuous portion of the first insulator material in a first plane below a first source or drain region of the first and second transistors, and a continuous portion of the second insulator material in contact with the continuous portion of the first insulator material, wherein the continuous portion of the second insulator material is in a second plane above the first source or drain region; and
the second insulator region includes:
a second continuous portion of the second insulator material in the first plane and in the second plane.

8. The IC structure of claim 7, wherein:
the continuous portion of the second insulator material of the first insulator region is in a same layer as a contact structure of the first transistor.

9. The IC structure of claim 1, wherein:
the first insulator region includes a first volume of the first insulator material and a second volume of the second insulator material; and
a ratio of the first volume to the second volume is in a range of about 1:1 to 1:9.

10. The IC structure of claim 1, wherein:
the first and second transistors are NMOS transistors; and
the third and fourth transistors are PMOS transistors.

11. An integrated circuit (IC) structure, comprising:
one or more stacks of nanoribbons, wherein the one or more stacks of nanoribbons include a first nanoribbon stack portion and a second nanoribbon stack portion;
a first spacer structure in the first nanoribbon stack portion electrically isolating a first transistor from a second transistor, wherein the first spacer structure includes a first insulator material between a first region of a doped semiconductor material of the first transistor and a second region of a doped semiconductor material of the second transistor, and a second insulator material over the first insulator material; and
a second spacer structure in the second nanoribbon stack portion electrically isolating a third transistor from a fourth transistor, wherein the second spacer structure includes the second insulator material between a third region of a doped semiconductor material of the third transistor and a fourth region of a doped semiconductor material of the fourth transistor.

12. The IC structure of claim 11, wherein:
the first insulator material has one or more different material properties from the second insulator material, including one or more of: material composition, density, and dielectric constant.

13. The IC structure of claim 11, further comprising:
a barrier layer on first sidewalls of the first spacer structure and on second sidewalls of the second spacer structure.

14. The IC structure of claim 13, wherein:
the first spacer structure includes an adhesion layer between the first insulator material and the barrier layer.

15. The IC structure of claim 14, wherein:
the adhesion layer is absent between the second insulator material of the second spacer structure and the barrier layer.

16. The IC structure of claim 14, wherein:
the adhesion layer is present at a bottom of the first spacer structure; and
the adhesion layer is absent from a bottom of the second spacer structure.

17. The IC structure of claim 11, wherein:
the first nanoribbon stack portion and the second nanoribbon stack portion are different portions of a same stack of nanoribbons.

18. The IC structure of claim 14, wherein:
the first nanoribbon stack portion is in a first nanoribbon stack and the second nanoribbon stack portion is in a second nanoribbon stack adjacent to the first nanoribbon stack;
the first spacer structure and the second spacer structure are in a same plane that is perpendicular to a substrate over which the first nanoribbon stack and the second nanoribbon stack are disposed; and
the IC structure includes the adhesion layer between and in contact with the first insulator material of the first spacer structure and the second insulator material of the second spacer structure.

19. A method of fabricating an integrated circuit (IC) structure, the method comprising:
providing a preliminary IC structure including one or more stacks of nanoribbons and regions of a doped semiconductor material in the one or more stacks of nanoribbons, the regions including a first region adjacent to a second region and a third region adjacent to a fourth region;
forming a first opening between the first region and the second region;
forming a second opening between the third region and the fourth region;
providing a sacrificial material in the first opening and in the second opening;
removing the sacrificial material from the first opening;
partially filling the first opening with a first insulator material;
removing the sacrificial material from the second opening; and
filling the second opening with a second insulator material, and filling the first opening with the second insulator material over the first insulator material.

20. The method of claim 19, further comprising:
prior to providing the sacrificial material in the first and second openings, providing one or more liners on sidewalls of the first opening and on sidewalls of the second opening.
